(19) United States
(12) Patent Application Publication
(10) Pub. No.: US 2020/0021270 A1
(43) Pub. Date: Jan. 16, 2020

(54) DIAMOND NANO RESONATOR SEMI CONDUCTOR

(71) Applicant: GREGORY WALKER JOHNSON, DAYTON, OH (US)

(72) Inventor: GREGORY WALKER JOHNSON, DAYTON, OH (US)

(73) Assignee: Gregory Walker Johnson

(21) Appl. No.: 15/998,162

(22) Filed: Jul. 11, 2018

(51) Int. Cl. H03H 9/17; H01L 29/16

(52) U.S. Cl. CPC H03H 9/171; H01L 29/1602

(57) ABSTRACT

A Diamond Nano Resonator Semiconductor, This is an Technology Light years Ahead of the 21^{st} Century. Diamond Sensors for your mobile Devices, such as a Cell Phone, Tablet, your Car, Buses, Commercial Airplane, Jets, Rockets, Satellites, Trains, Televisions, Radio, Diamond™ Smart Watch, Power Plants, Cell Phone Tower, everything will run on Synthetic Diamonds, Because nothing can transfer Heat and Conduct Electricity like Synthetic Diamonds, these Diamonds™ Coated Semiconductor runs on tiny Synthetic Nano Resonators in any size and shape, with Encryption Software in an Pseudonymous Format. All Figures will have this ability. And some will run on Anti Matter.

### BACKGROUND OF THE INVENTION

This application claims priority from a utility application Ser. No. 14/545,605 Filed May 29, 2015.

This is Related to Computer Technology the most Advanced Hardware and Software in the 21^{st} Century, Entitled Super Diamonds Nano Tech, Synthetic Diamond Nano Resonators made for A Mother Board, Cell Phone, laptop, Desktop, MP3 Player, Tablet, AI Cars, Boats, Planes, Rockets, Portable Game Player, Credit Card, Wireless Ear Plugs, Wireless Head Sets, Washer's Dryers, All Run On Synthetic Diamonds, that can continue to run forever on Anti Matter, Harness from the Sun and Methane Gas and Hydrogen as well, The Data Center will have a Cooling from System Synthetic Diamonds the most Advanced Technology in the Universe, That can Transfer Heat and Conduct Electricity like Nothing ever before in the History of Mankind, Silicon is basically Dead in the 21^{st} Century because after 150 degrees Celsius the Mother Board will began to Burn. Ships everything will Run on Synthetic Diamonds, And AI tech, With All Sizes of Synthetic Diamonds for every Item, this can endure heat, and cold like never before A Thousand Times Smaller than the width of a Single Strand of Human Hair that has Robust Power unmatched in the history of mankind that vibrate at 100 Billion Times a Second Nano Resonator, I will also use Black Diamonds as well, (AKA) Carbonado.

I Gregory Walker Johnson will Manufacture Total Black Diamond Wafer™ (AKA) Carbonado, Sprinkle with Synthetic Diamond Crystal's and microchips from the wafer, A Semiconductor Diamond Synthetic™ Tiny Synthetic Diamond Resonators™ Encryption Software in a Pseudonymous format™ Solar energy and Helium, Methane gas, Hydrogen, and Carbon, all Hardware will run on Synthetic Diamonds. All Shapes, and Sizes Synthetic Diamonds. All will Harness by the Natural Elements. And Total Synthetic Diamond Wafer™, Sprinkle with Synthetic Diamond Crystal's and microchips made from The Wafer, as well, The Mother Board, Made from Synthetic Diamond Crystal's. A Synthetic Diamond™ Battery with Fire Proof Electrolyte also. Diamond™ Sensor's Synthetic.

Diamond Sensor's Synthetic and Energy And Power Plants.

### BRIEF DESCRIPTION OF DEVICE

Fig. I Shows front view of Solar Tablet™ Verbal with features TV, phone, news, weather, entertainment BCCR™ Built in Credit Card Reader Software™, with camera. speaker ear plug port menu button beep paid credit card 1 1A attachable and detachable keyboard USB port Light Window Port Scan close to software terminal for beep paid credit card IIA.

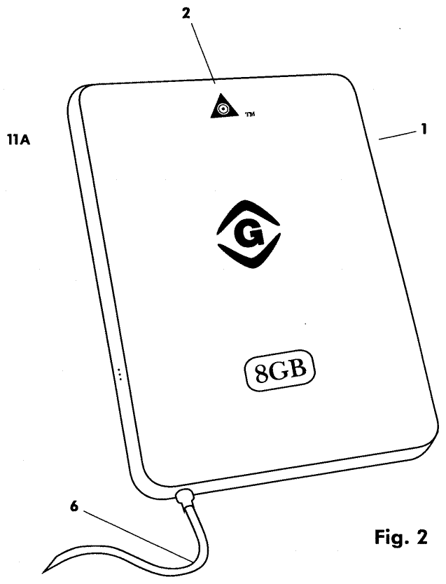

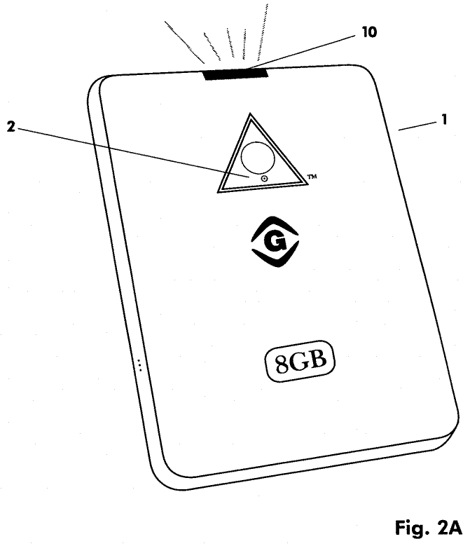

FIG. 2 Shows. back view of solar tablet with back facing camera, ear plug port. and built in credit card reader 1l.A and boomerang Swiss G logo. FIG. 2.A A Built in Projector Camera On Tablet Back, solar screen Swiss G logo.

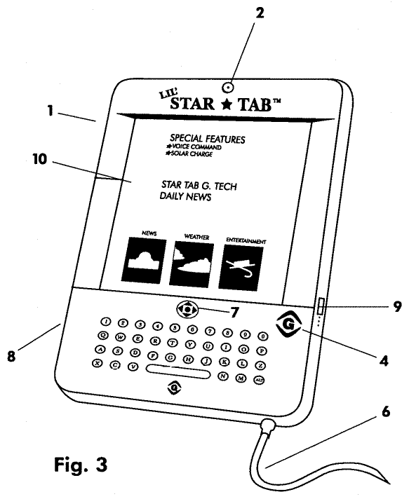

FIG. 3 Shows solar tablet for Lil kids tablet. with features and camera speaker. with ear plug port and menu button attachable and detachable keyboard USB port Light W:indow Port (LWP).

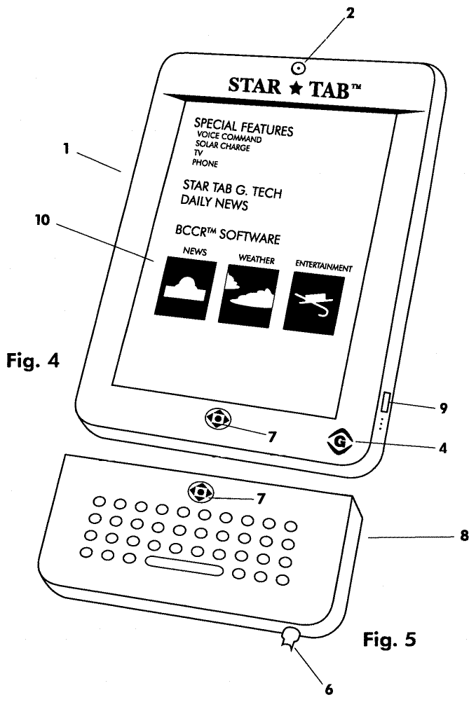

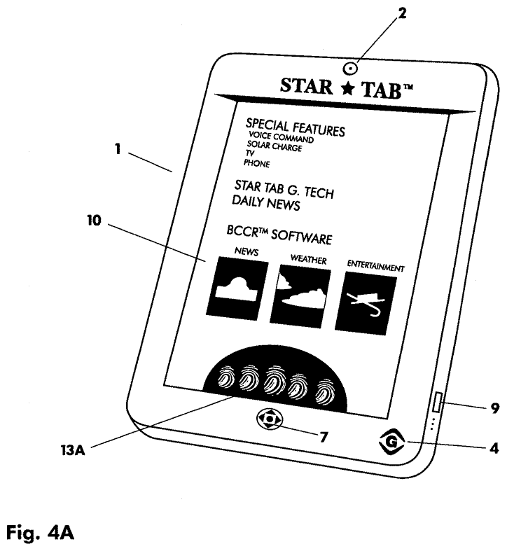

FIG. 4 Shows solar tablet™ Verbal features news, weather, entertainment, television, phone, built in credit card reader software, with camera speaker. menu button USB port 9. and Light Window Port (LWP) FIG. 4A 5 finger print scanner on the tablet 13A.

FIG. 5 Shows actual attachable and detachable keyboard ear plug port. menu button

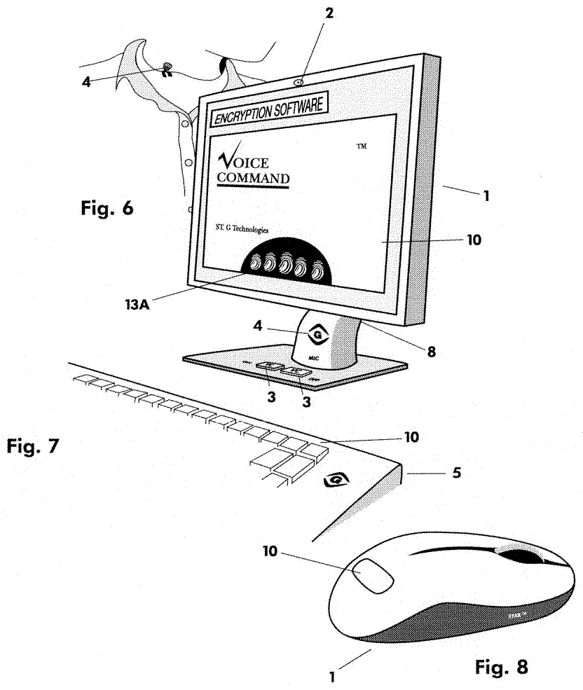

FIG. 6 Shows. solar wireless Desk Tab™. with camera. with verbal command buttons for tlmling on and off speaker and where it is attachable and detachable Desk tab™ finger print scanner on screen

FIG. 7 Shows front view solar wireless keyboard and Light Window Port (LWP)

FIG. 8 Shows front view of a solar wireless mouse. with a Light Window Port (LWP)

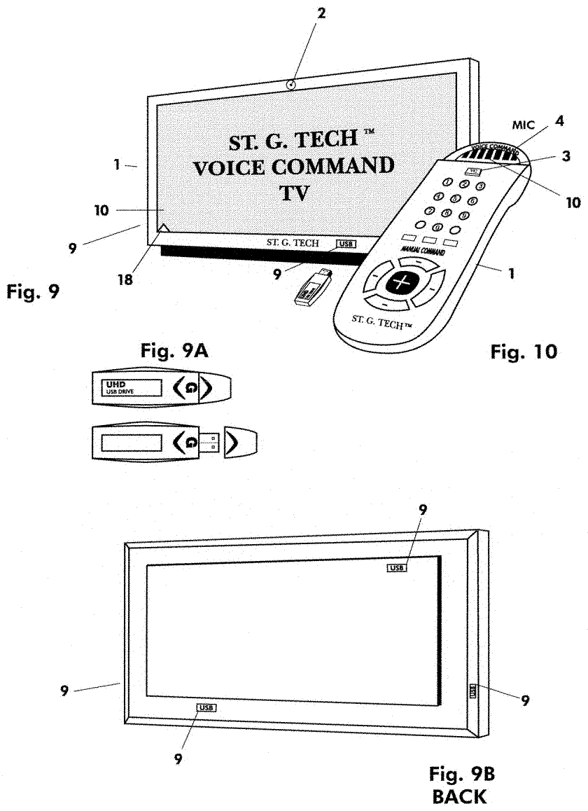

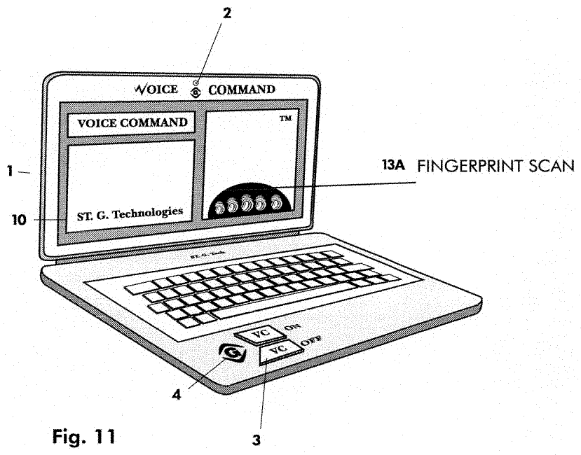

FIG. 9 Shows front view of wireless solar verbal command television. with. a camera′. USB Port Light Window Port (LWP). built in wireless receiver. 9 A shows UHD flash drive for USB in back of TV for Streaming movies. 9B back view upper right corner and bottom left corner and right and left side view of USB Port.

FIG. J O Shows front view of a solar verbal remote control 1. with VC on and VC off button speaker. Light Window Port

FIG. 11 Shows. front view of a solar verbal command laptop with camera′ VC on and VC off buttons speaker and Light Window Port (LWP). 5 finger print scanner.

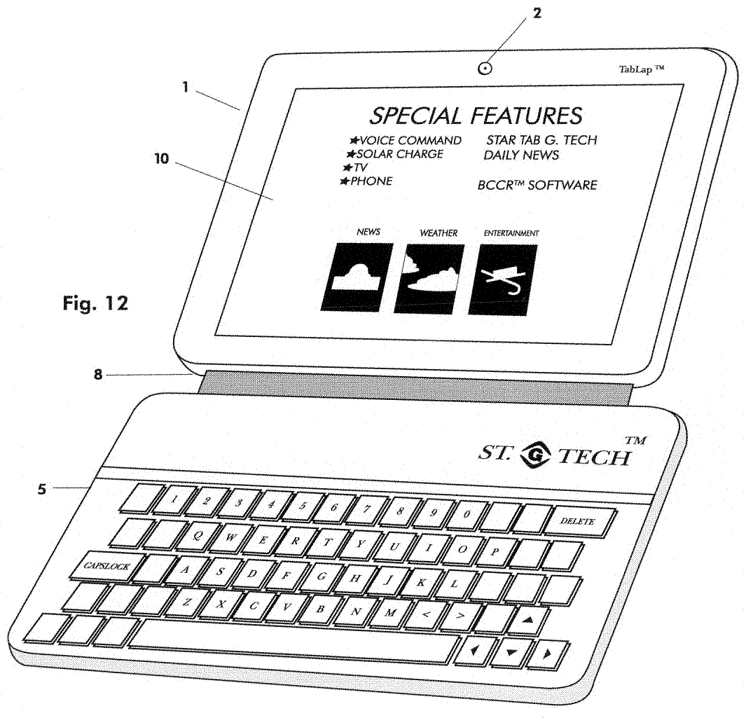

FIG. 12 Shows front view of a solar attachable and detachable tablet, called the Tab lap™. with phone, TV, weather, news, entertainment, with built in software credit card reader, with camera key board where it is attachable and detachable keyboard 8. Light Window Port (LWP)-

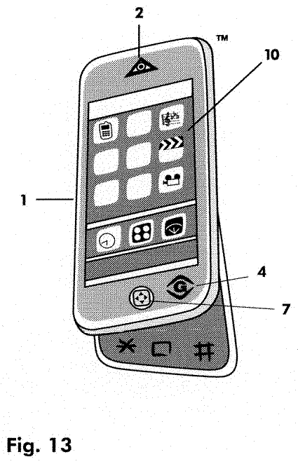

FIG. 13 Shows front view of a solar touch screen on the top and push button on the bottom verbal command Flip Phone™ l. with camera speaker menu button and Light Window Port (LWP). Runs on Nano Resonators.

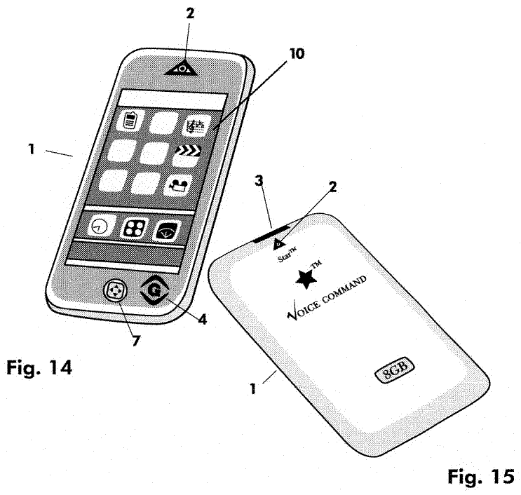

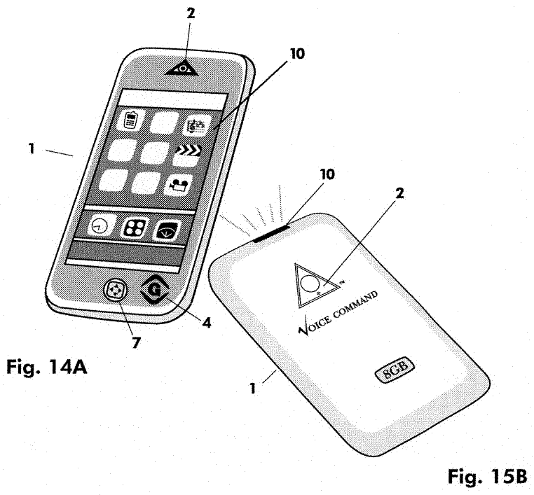

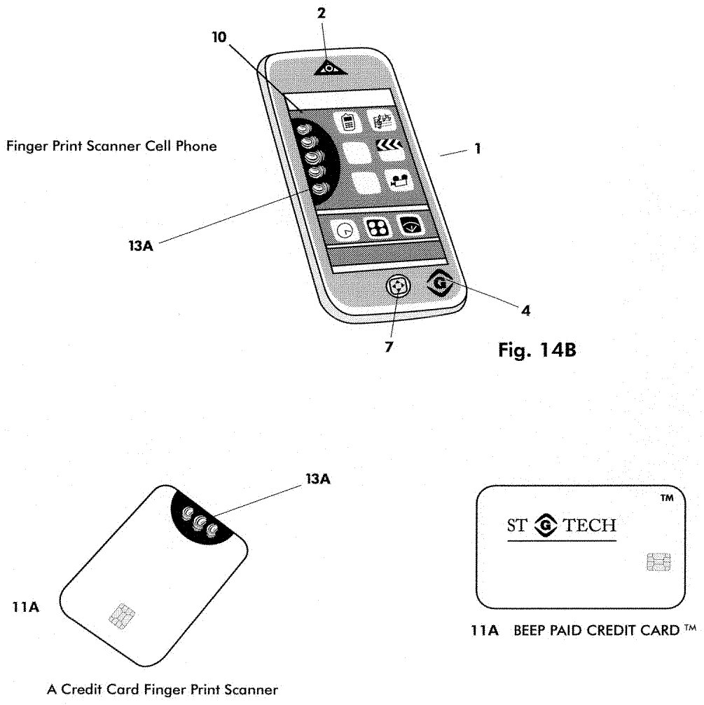

FIG. 14 Shows. front view of a solar verbal command cell phone camera. speaker menu button Light Window Port (LWP) l4B show side way 5 finger print scanner 11A 3 finger print scanner l 1 A beep paid credit card. Fig. l 4A Cell Phone.

FIG. 15 Shows back facing camera and VC on and off buttons of solar verbal command cell phone. FIG. 15B Shows back of cell phone with built in projector solar screen.

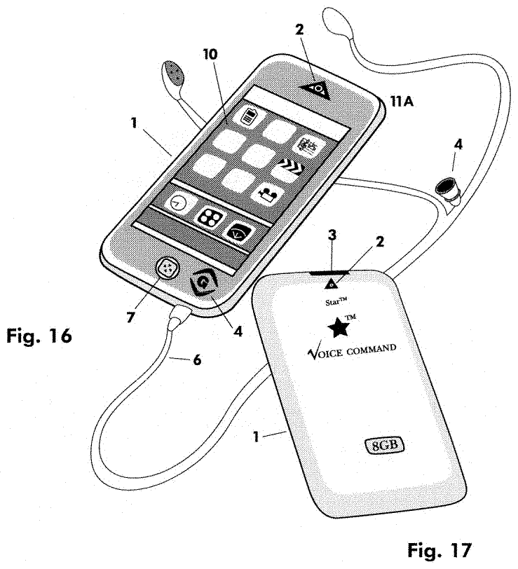

FIG. 16 Shows front view of solar verbal command MP3 player with camera speaker ear plugs menu button Light Window Port (LWP) and Built in Beep paid credit card

FIG. 17 Shows back view of a solar verbal command MP3 player with back facing camera and VC on and VC off buttons

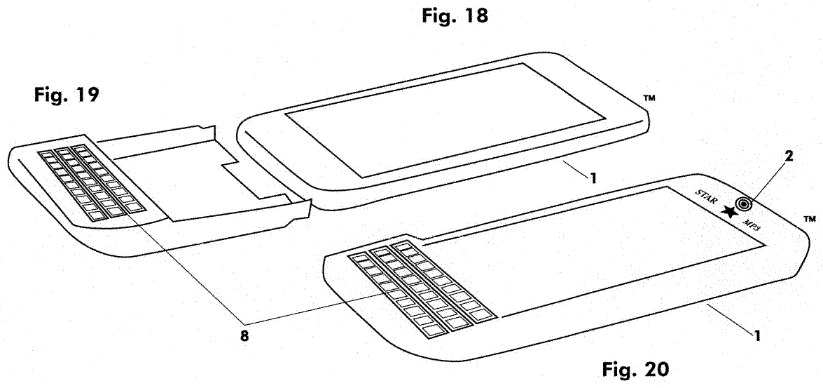

FIG. 18 Shows front right side view of an attachable and detachable MP3 player

FIG. 19 Shows front right side view of attachable and detachable keyboard

FIG. 20. Show front right side view of attachable and detachable keyboard With camera. on MP3 player and how it works 8. Will run on tiny diamond Nano Resonators.

FIG. 2 I Shows front left angle view of a solar wireless cash register with Light window Port (LWP)

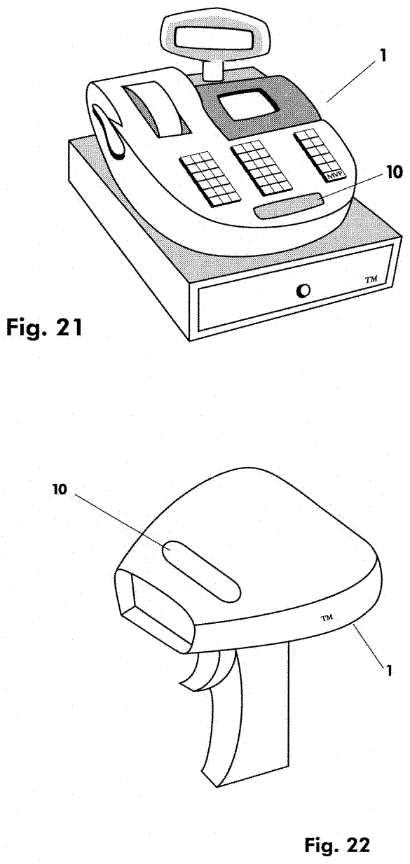

FIG. 22 Shows front right angle view of a wireless scanner with Light Window Port (LWP).

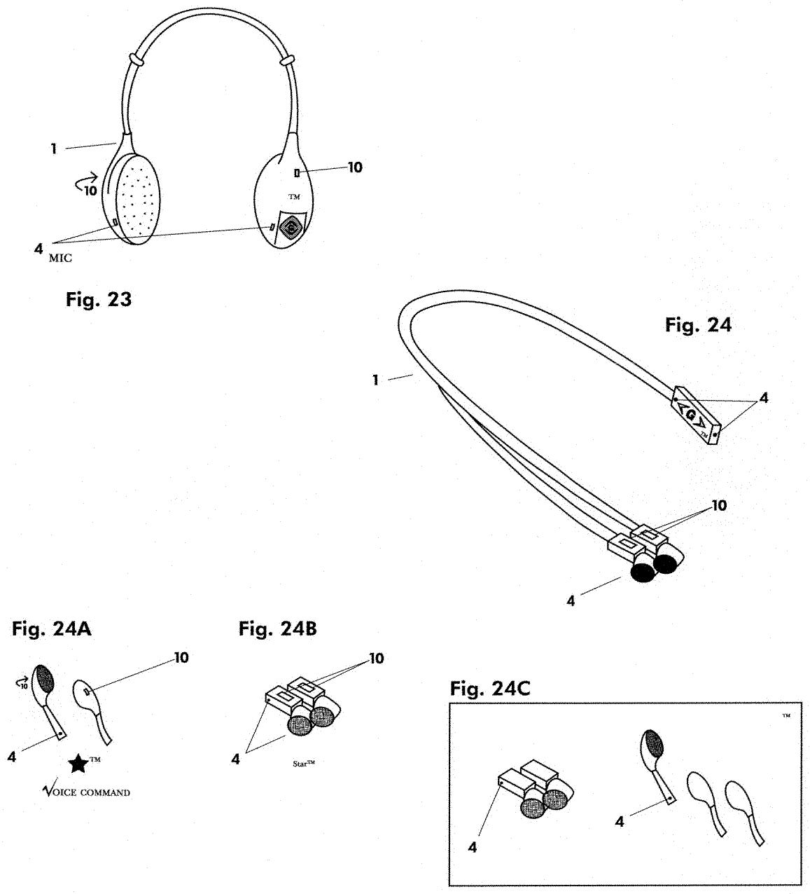

FIG. 23 Shows front view of Star™ wireless headset for music and speaker on both sides solar window port with mic on both sides.

FIG. 24 Shows front view of wireless ear plugs both run by software, and speaker 4. FIG. 24A Shows wireless earplugs with speaker and solar (LWP) 24B Shows two pair of wireless earplugs with speaker 4.24C shows two pair and one single earplug all with no (LWP).

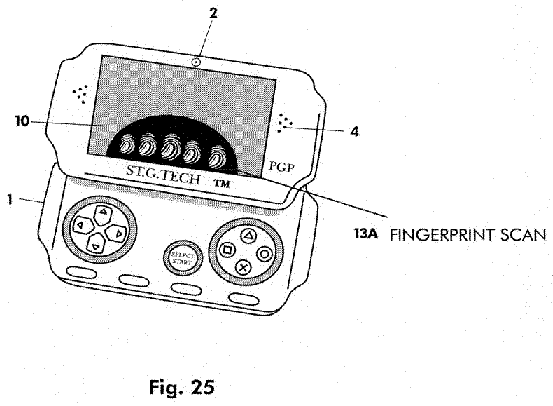

FIG. 25 Shows. front view of a verbal solar portable game player with camera. speaker 4. Light Window Port (LWP With 5 finger print scanner

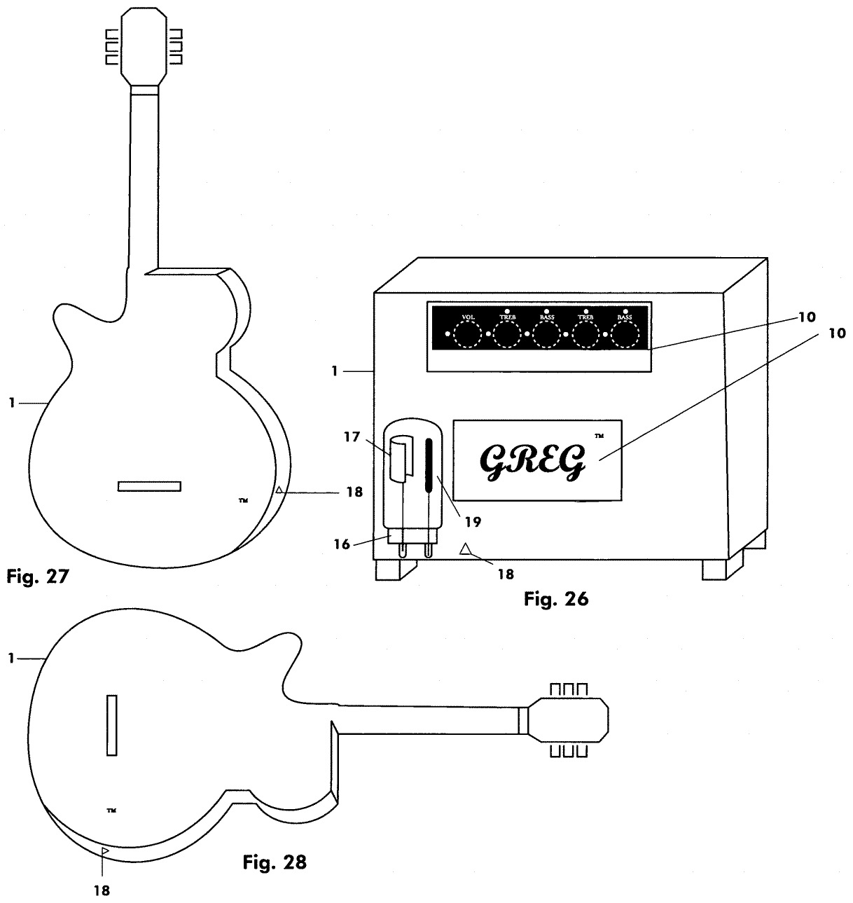

FIG. 26 Shows front view of a solar wireless speaker with Light window Port (LWP) . Wireless amplifier with cathode and anode that produce electrons that make sound, and speakers work and wireless receiver. in amplifier and on guitars. Broken lines around volume, treble, bass knobs are for illustration only and are no part of invention. Huge Speakers for live bands recording artist as well.

FIG. 27 Shows. front view of wireless guitar with wireless receiver

FIG. 28 Shows side view of wireless guitar with wireless receiver.

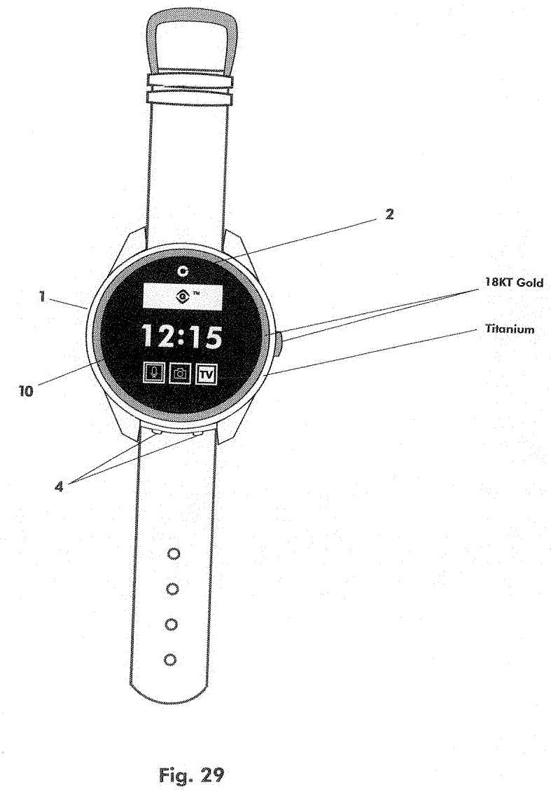

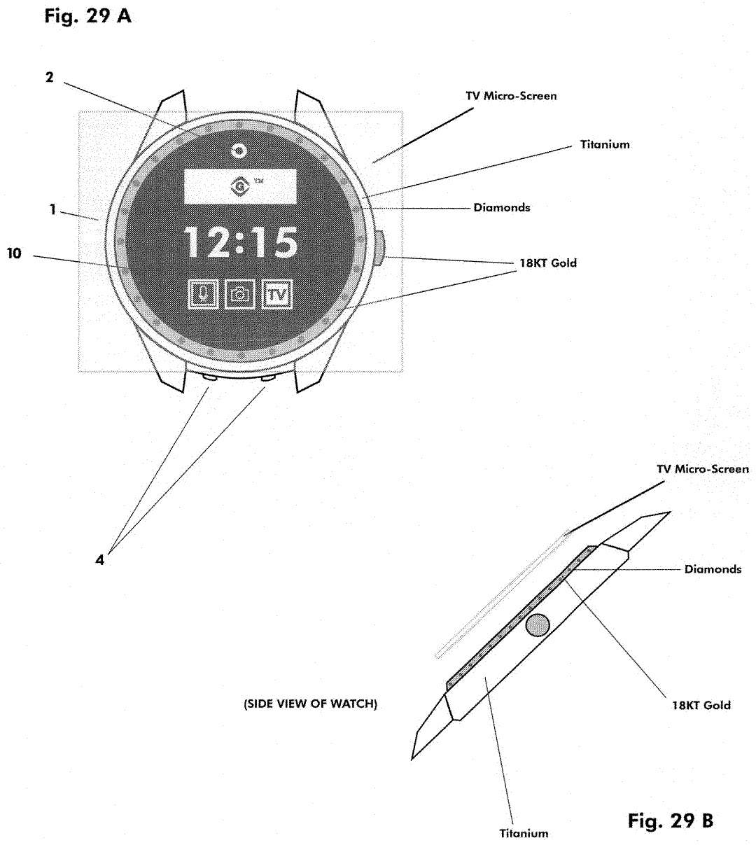

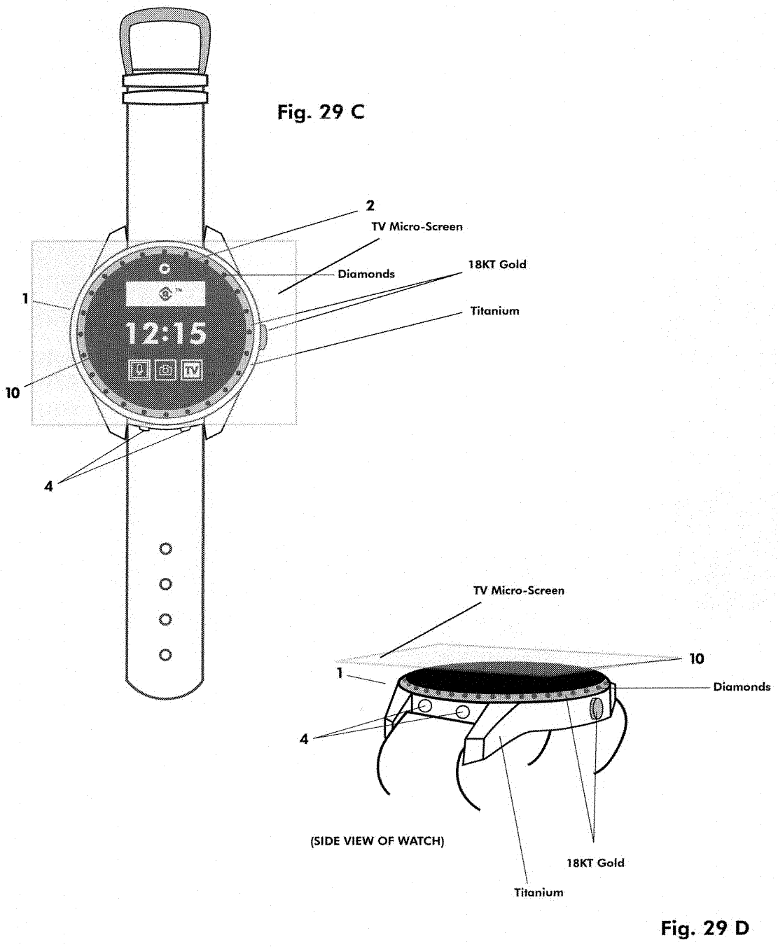

FIG. 29 Shows front view of a solar wireless smart watch with camera. features, TV, verbal can be made of stainless steel also.

Commands speaker on the right side and microphone on the left side, Light Window Port (LWP) 29A AI watch with movie screen 29B side view of smart watch 29C front view of smart watch 29C and D with TV on it.

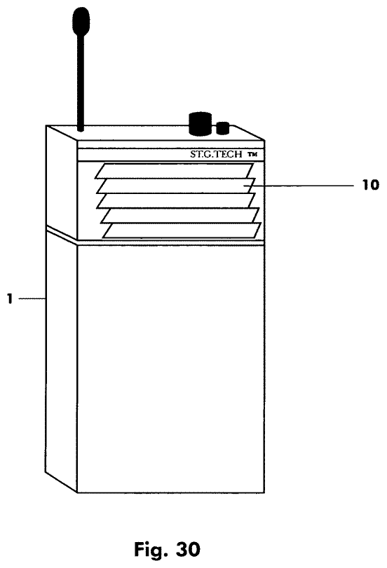

30.29 FIG. 30 Shows front view of a solar 3 way wireless radio “with 5 Light Window Ports (LWP that run on Nano Resonators.

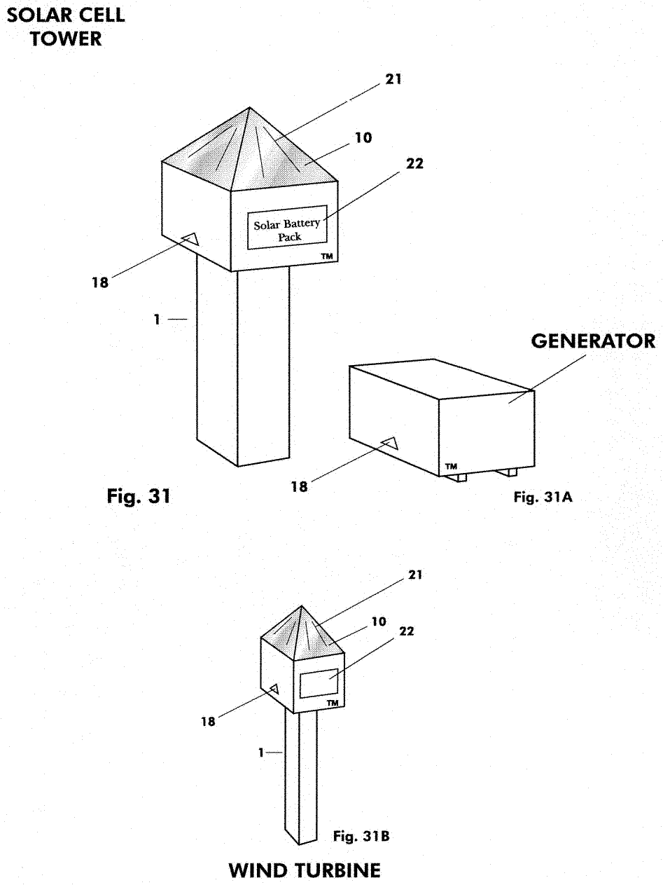

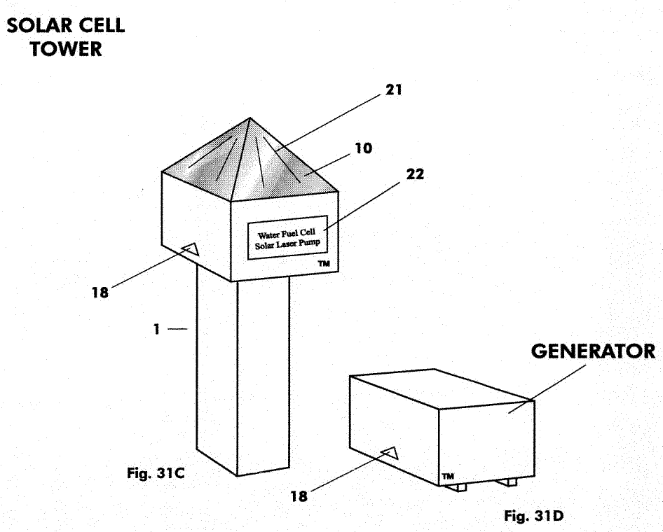

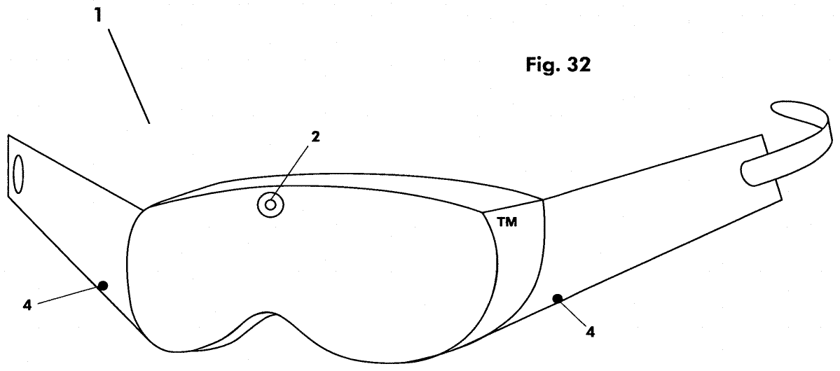

FIG. 31 Shows. front view of a solar cell phone tower Light Window Port (LWP) Wireless transmitter generator,

Solar panel Solar battery pack 31 A with generator, wind turbine 3lB water fuel pump cell phone tower 31C wireless transmitter. Generator 31D. Solar panels . Water Fuel Cell Solar laser pump Light window Port

FIG. 32 Shows front right view AI Augmented Glasses for movies making movies Video, Music wireless reality Glasses take Pictures, by AI voice command wireless produce movies on your Glasses music, Streaming movies, Games online forums share anything by AI Phone calls, Television.

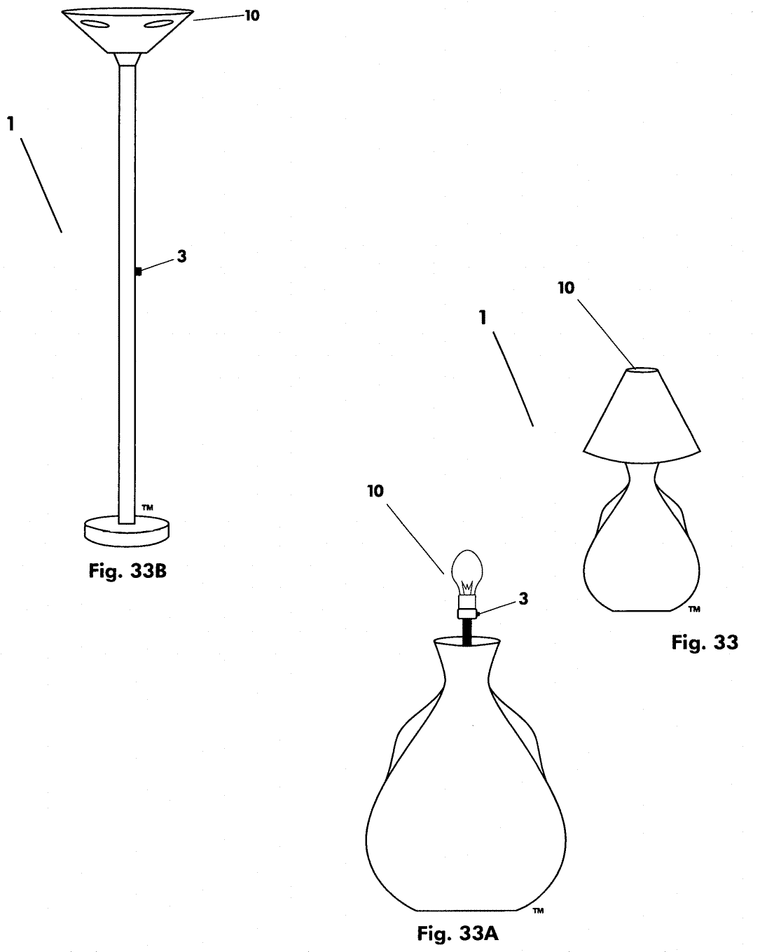

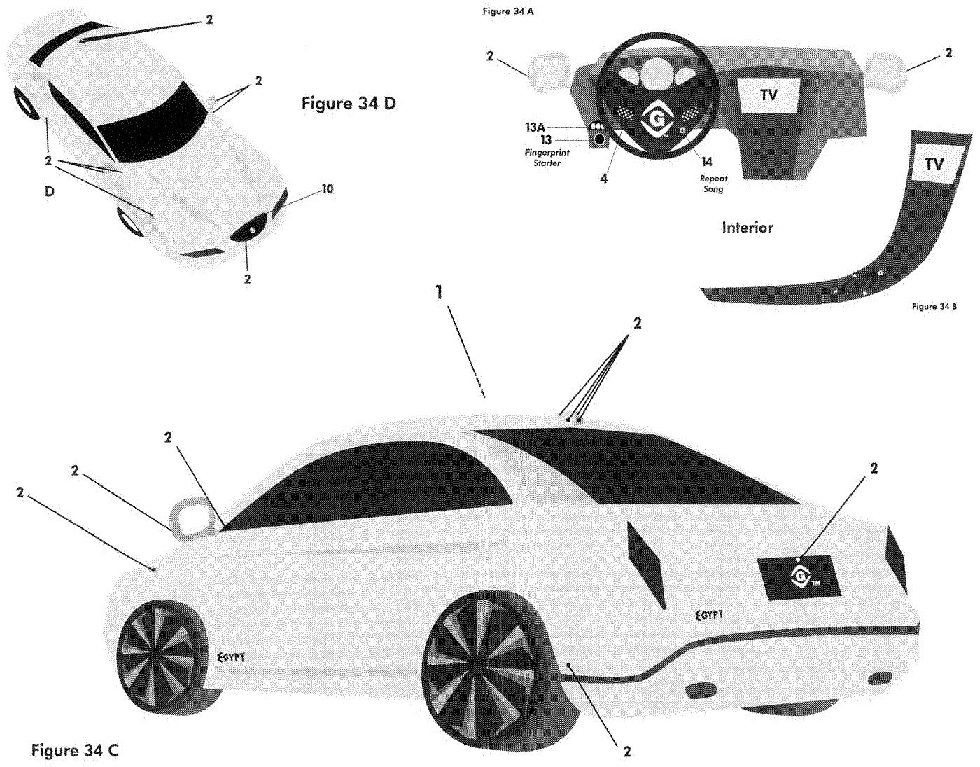

FIG. 33 Shows. front view wireless lamps, with a Shade A without a shade B and tall lamp C.

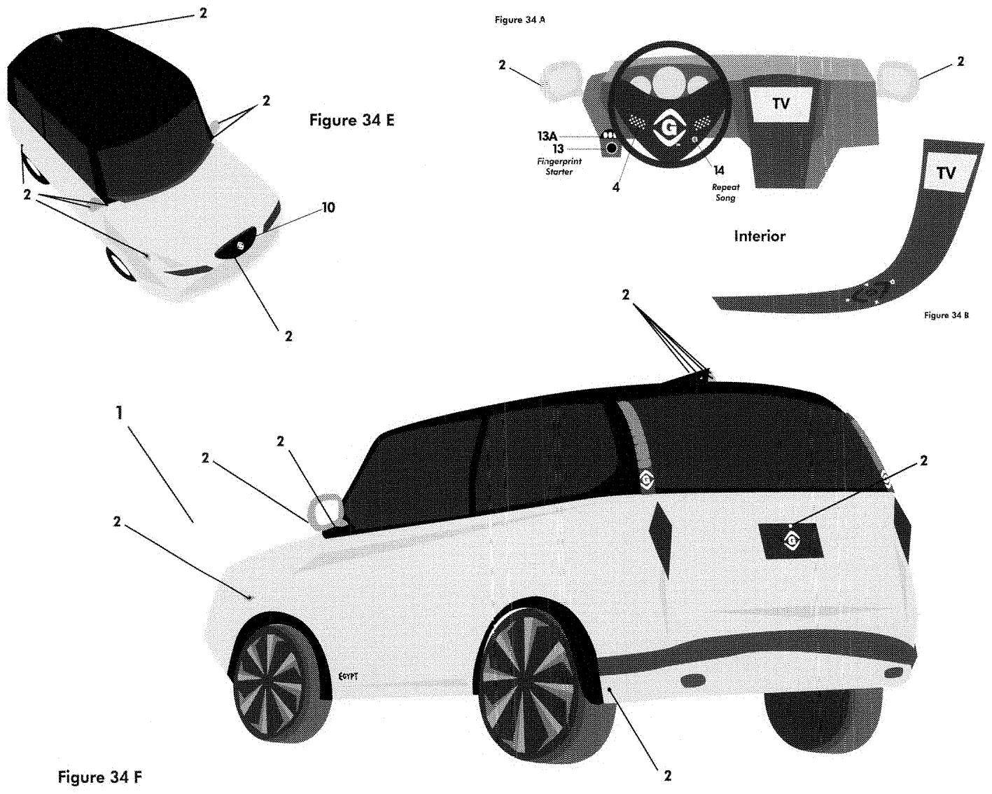

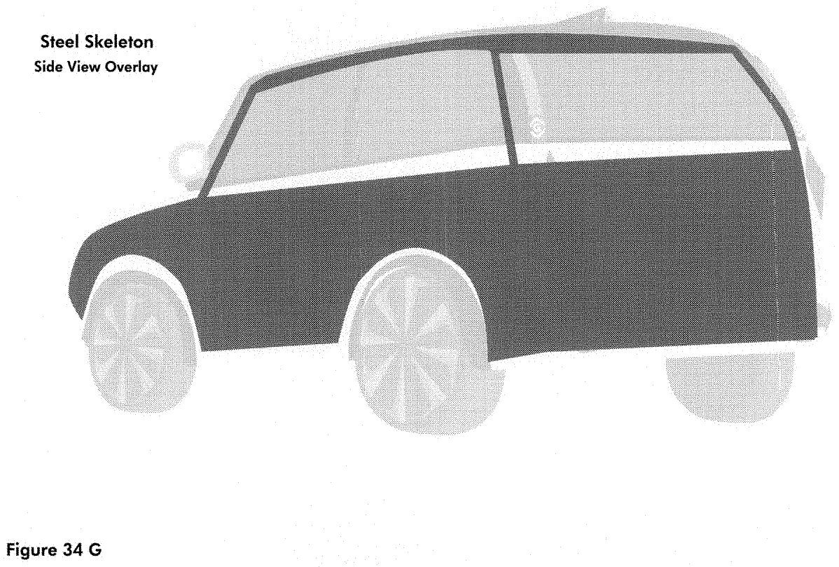

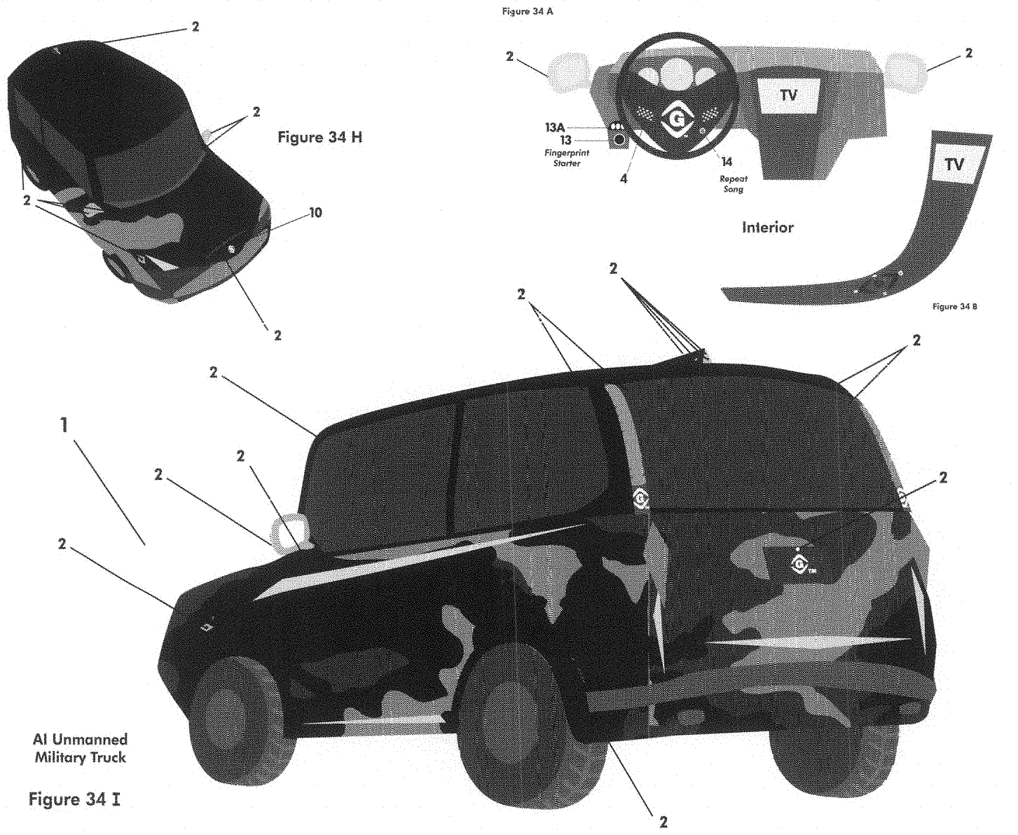

FIG. 34C Shows 1 front left side and back view of Al electric car with. cameras total cameras, and where positioned, fig. A. dashboard with steering wheel that user speak into to comm1micate And repeat song selection manually, and by voicefinger push button starter, and finger print scanner. Fig. B. Television and drive and park gear change, fig. D front left view of car with cameras, fig. E SUV front left view with cameras, fig. F SUV left side view and back view fig. G shows left view and back view of SUV with solid steel that will be 3 inches thick the new protection from crashes, fig. H. front left view of AI Unmanned Military Truck

Fig. I. left side view and back view with cameras on the inside can be operated with or without a man, all vehicles will have Encryption Software in a Pseudonymous format, that can open and close doors, by AI voice command, Park by AI voice command as well, the car can take pictures also and can understand any foreign language as well, all vehicles will run on synthetic diamond resonators, and Anti Matter also.

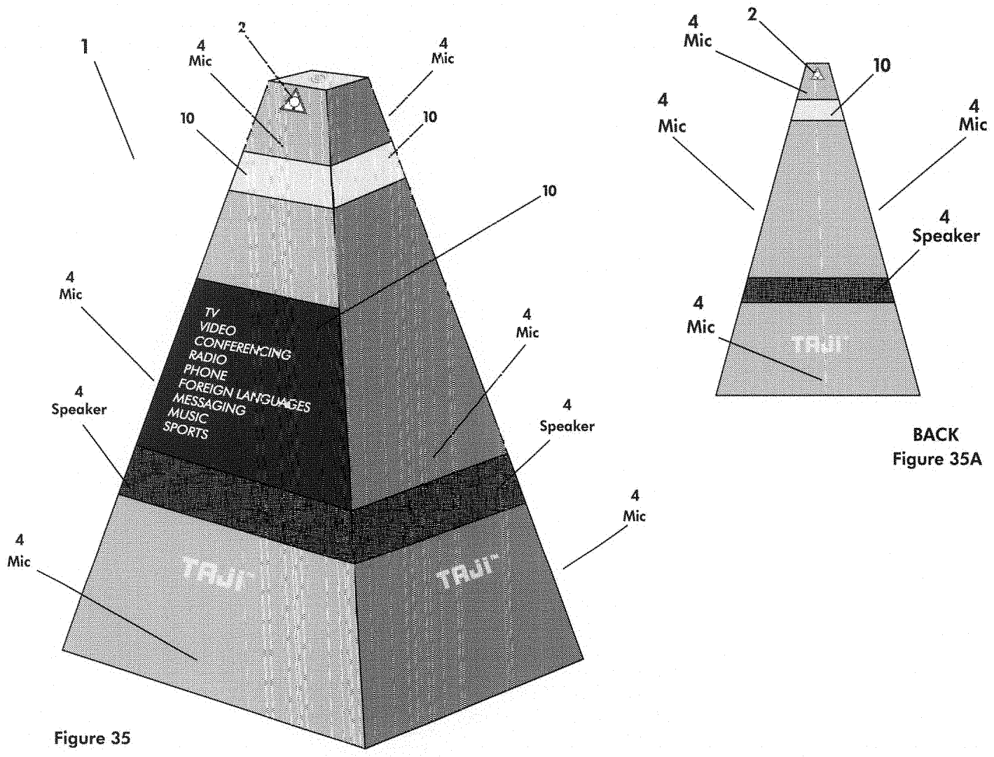

FIG. 35 Shows. front right view first. Mobile Home assistant Called Taji and back view with mic's all around the m1it and one front and back facing camera. Sports Television, Phone, Messaging, Radio, Video Conferencing, Music, Foreign Languages Encryption Software in a Pseudonymous format, take it anywhere you go.

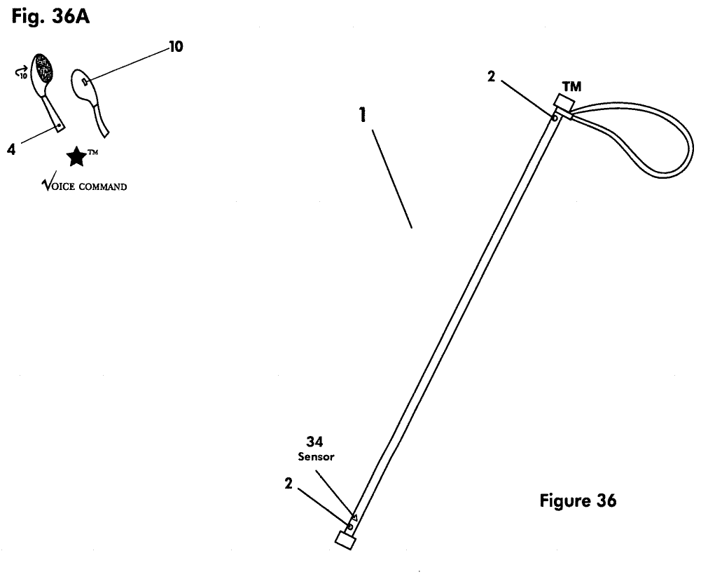

FIG. 36 Shows. front view first Electronic Cane with camera a Solar Wireless earplugs it is AI as well. Sensors to detect a car is coming and when to walk Phone Ready also.

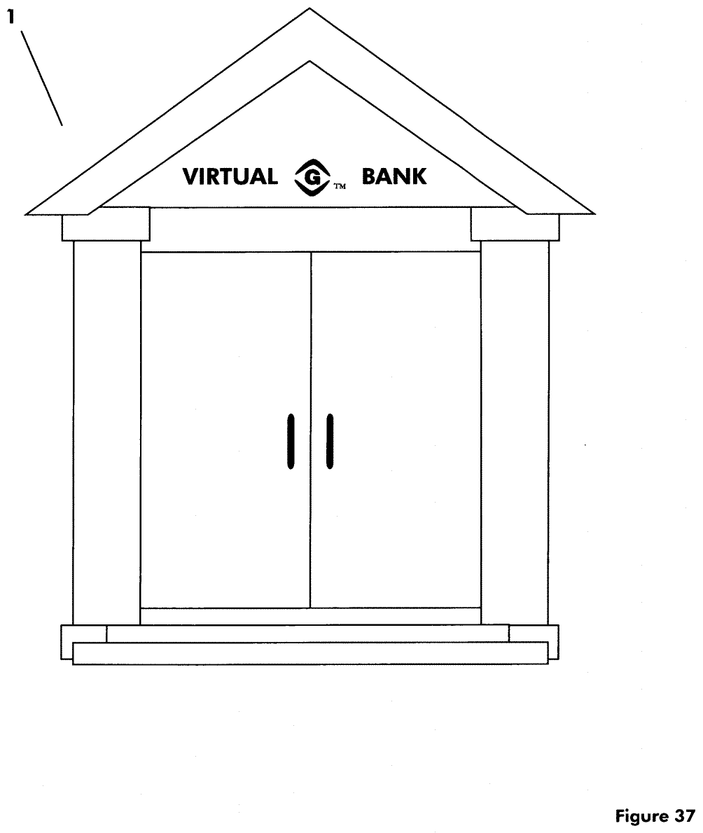

FIG. 37 Shows; front view AI Virtual Bank Crypto Currency AI as well, buy and sell anything, clothes, jewelry, property Cars, insurance.

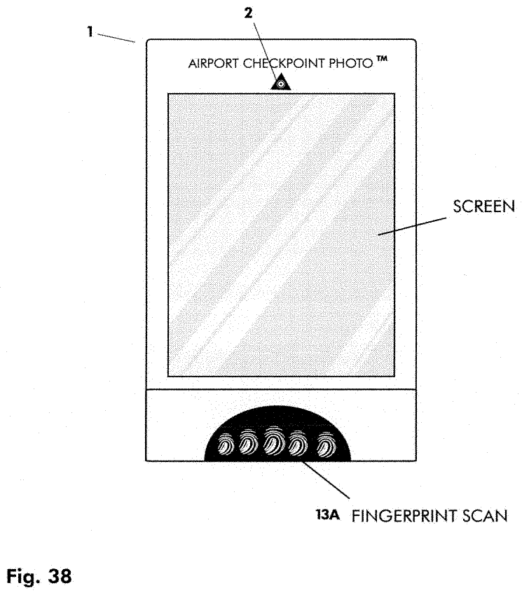

FIG. 38 Shows front view 5 finger print scan, A′ Airports Check Point, Camera_

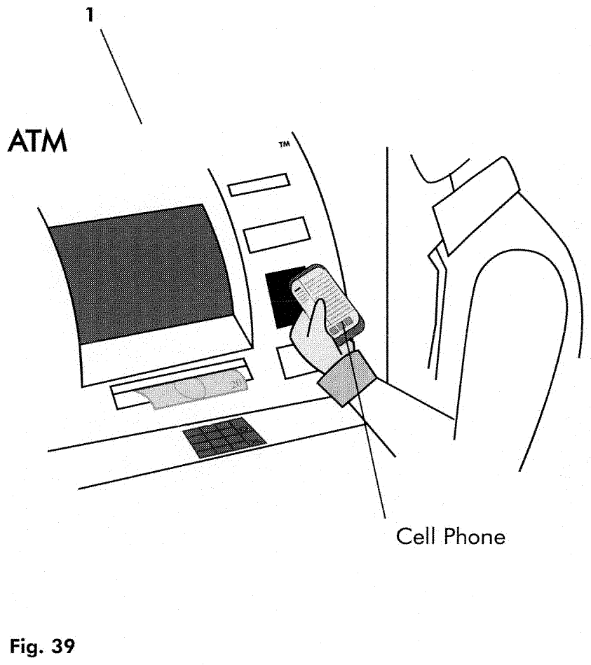

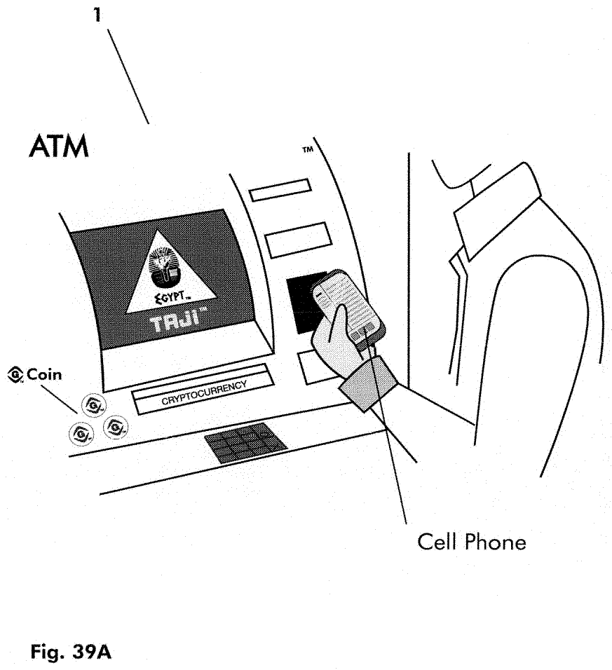

FIG. 39B Shows front view AI ATM Machine to transaction for Crypto Money by cell phone your watch or mobile device

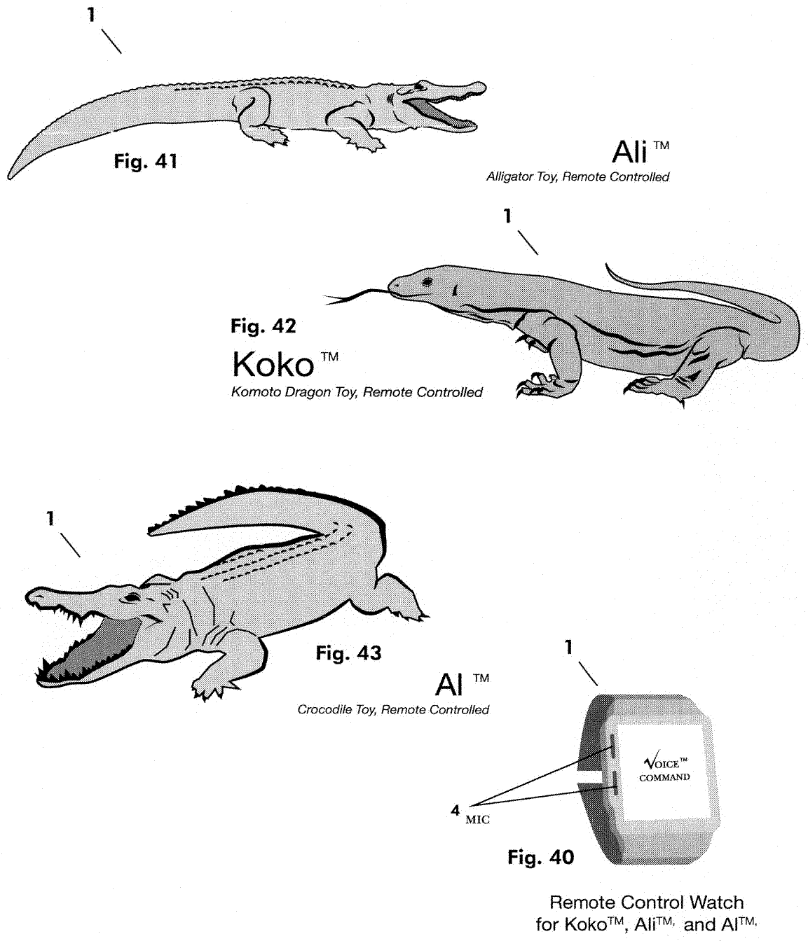

FIG. 40 Shows. front view AI Watch for Toys

FIG. 41 Shows front side view AI toy Alligator

FIG. 42 Shows front side view AI Toy Komoto Dragon KOKO

FIG. 43 Shows front side view AI toy Crocodile

FIG. 44 Shows front right side AI Electric Motorcycle

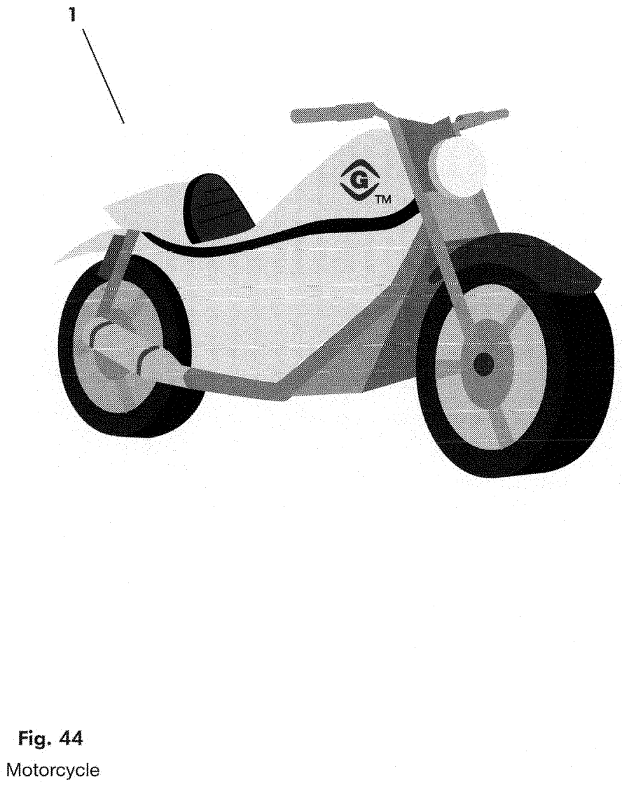

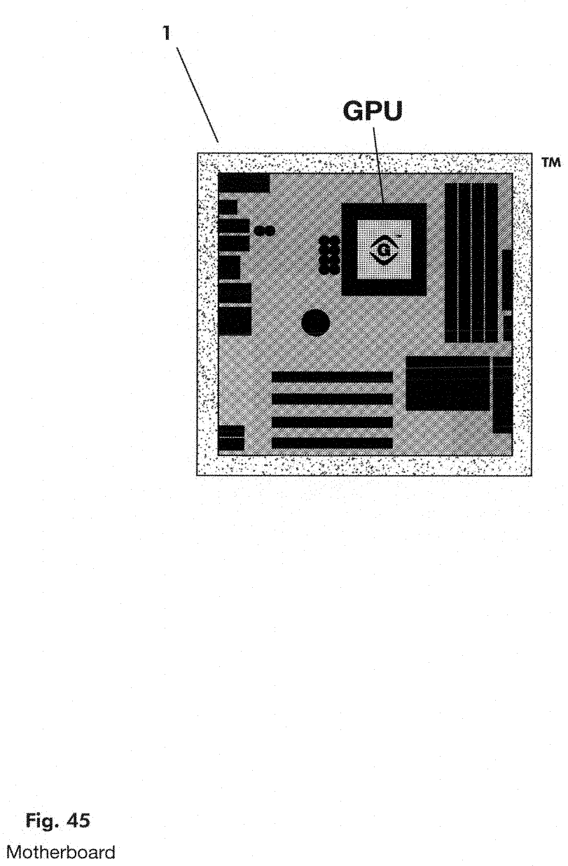

FIG. 45 Shows front side Diamond Synthetic Mother Board Graphic Processing unit

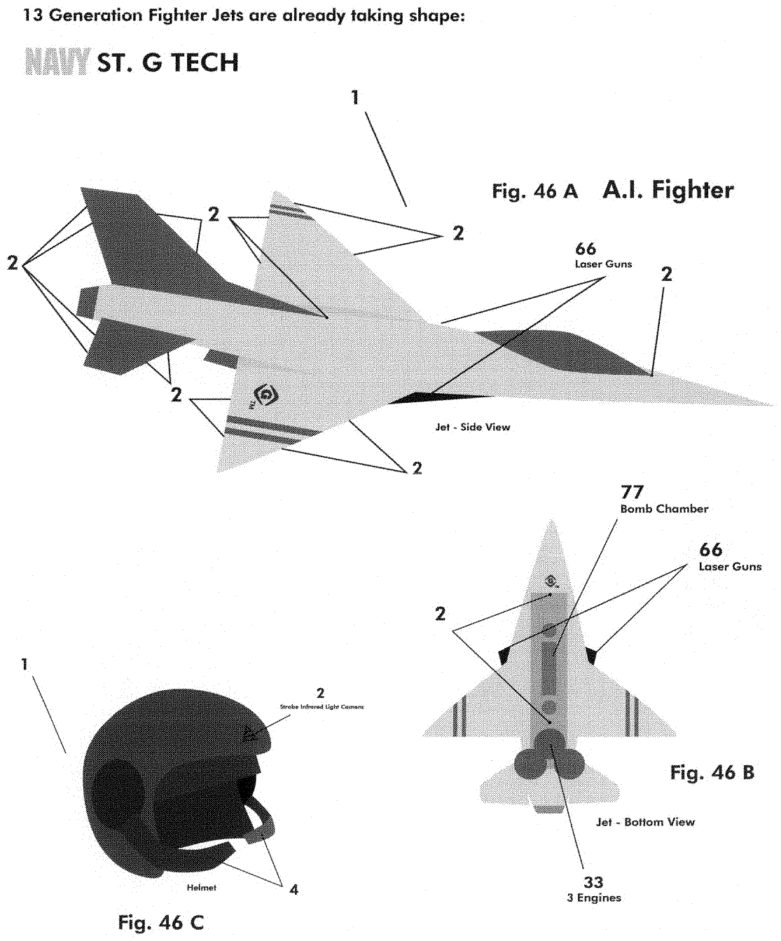

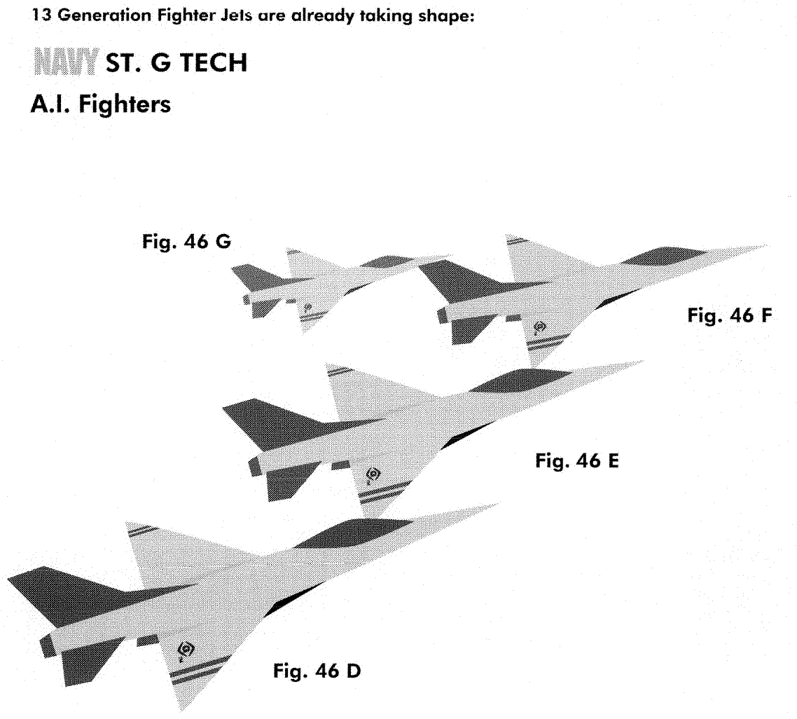

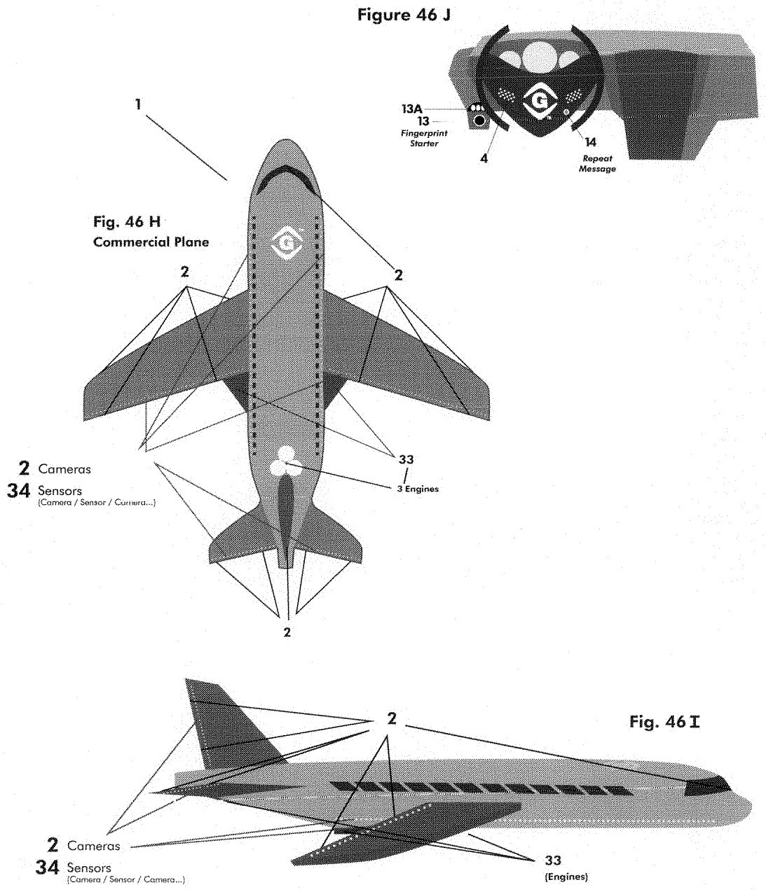

FIG. 46 Shows: front right side AI Jet fighter that will have Mach 66 speed harness by Hydrogen, Helium, Methane Gas Solar with three modes 1st Jet, 2nd Supersonic 3rd Rocket, all from the same aircraft that could stay in orbit for ten years or longer body made of Synthetic Diamonds, and Anti Matter, the body made of synthetic diamonds Plasma to make it front Stealth, with ICBM ability and laser Guns as well this is the ultimate 21st Century Fighter, with Nano Resonators. With Camera on the Jet 46B is the Rocket 46 C is the AI Helmet. With Infrared light camera on top of helmet. will run on Anti Matter. Laser Guns on right and left bottom view Bomb Chamber

The windows on the Planes, commercial and jet fighters will be made of synthetic diamonds, cameras, windows made of Synthetic Diamonds on all Planes,

FIG. 46 D Shows front right view of AI Jet Fighters formation that be totally unmanned as well

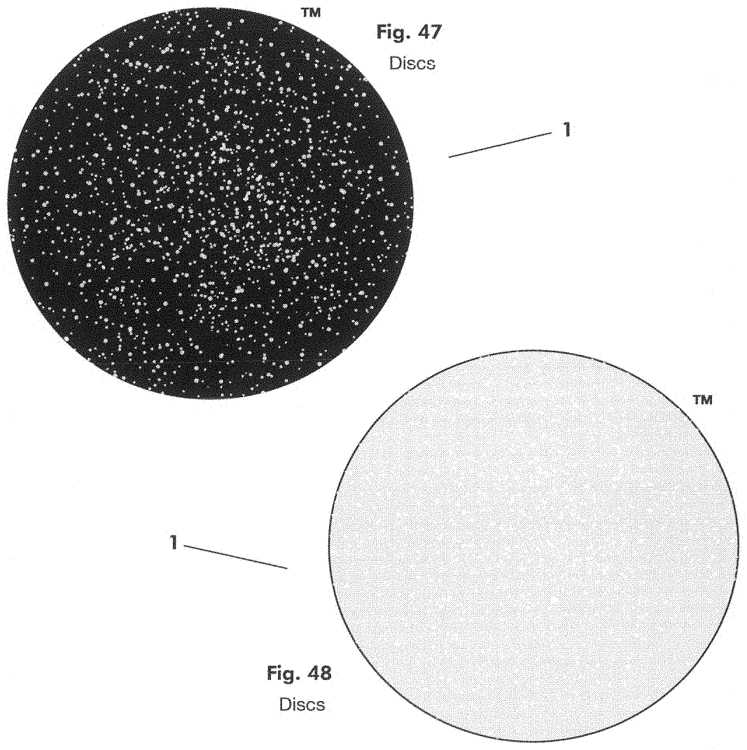

FIG. 47 Shows front view all Diamond Wafer that is Black Diamond (aka) Carbonado that Microchips will be made from, sprinkled with synthetic diamond crystals.

FIG. 48 Shows. front view all Synthetic Diamond Wafer that Microchips will be made from Sprinkled with synthetic diamond crystals.

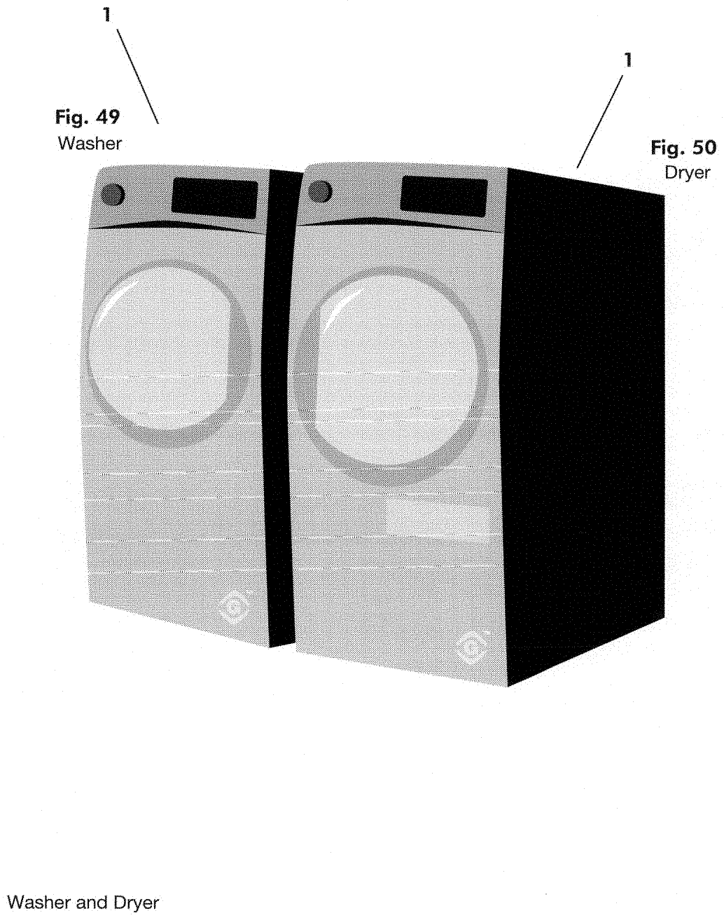

FIG. 49 Shows front view Smart washer that will call user and tell him when the load is finished washing.

FIG. 50 Shows front view Smart Dryer that will also call user on their Cell Phone or any mobile device.

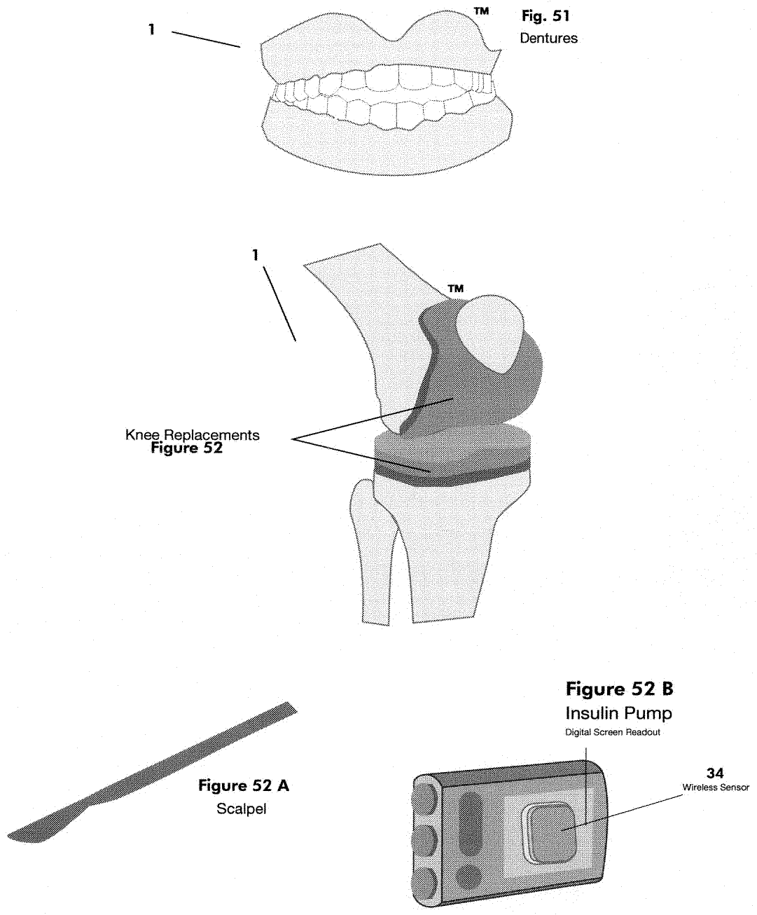

FIG. 51 Shows front view Set of Dentures that will be made from Synthetic Diamonds.

FIG. 52 Shows front view Knee Replacement as well will be made from Synthetic Diamond 52 A Scalpel 52B insulin Pump 34 wireless sensor. Digital Screen Readout. With Encryption Software in a Pseudonymous format.

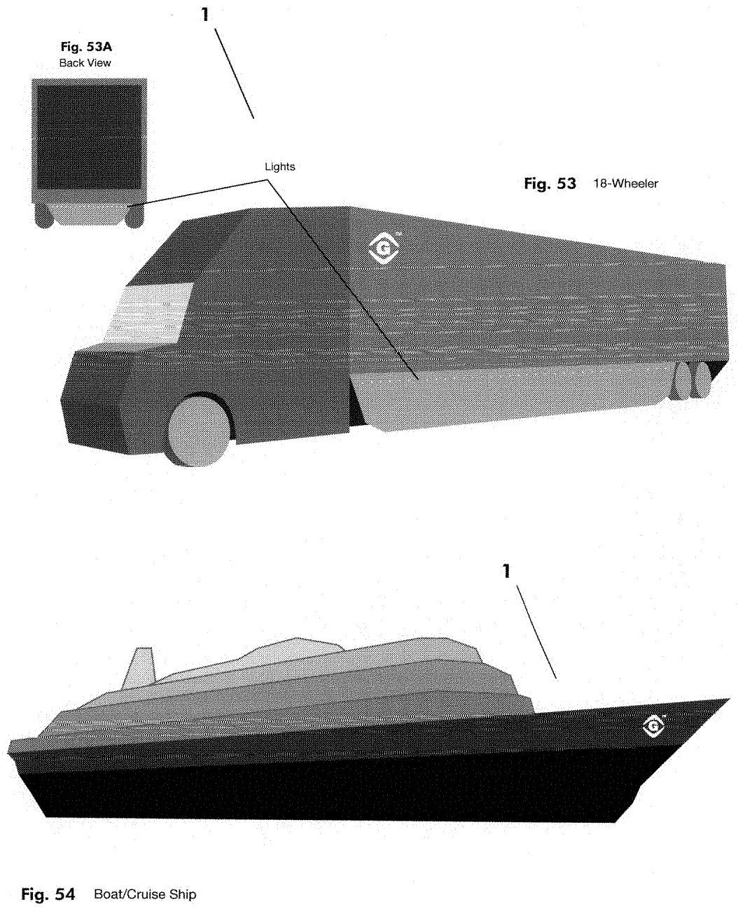

FIG. 53 Shows front right view Electric AI 18 Wheeler with Braces on the side and back to stop cars from running under the truck. 53A Back of Truck.

.FIG. 54 Shows front right view AI Electric Cruise Ship that run on diamonds.

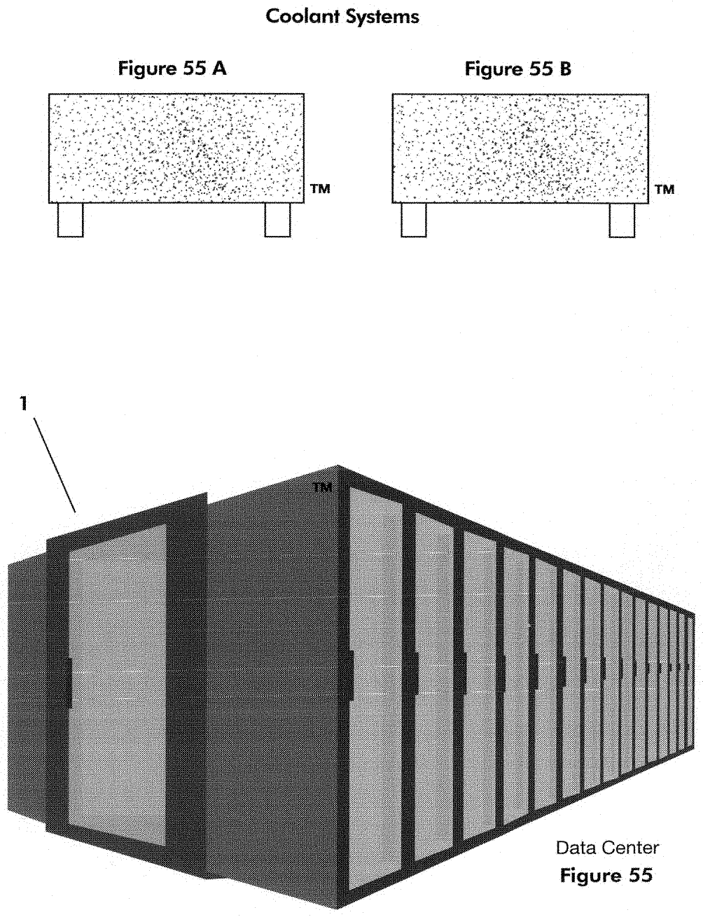

FIG. 55 Shows front right view of AI Data Center that is wireless Solar with Diamond Resonators Coolant System, 55A and 55B the Data Center will have 10,000 processing chips, and 33,000 graphics processors, the system will run on synthetic diamonds. And Servers, and drives, all run on Synthetic Diamonds.

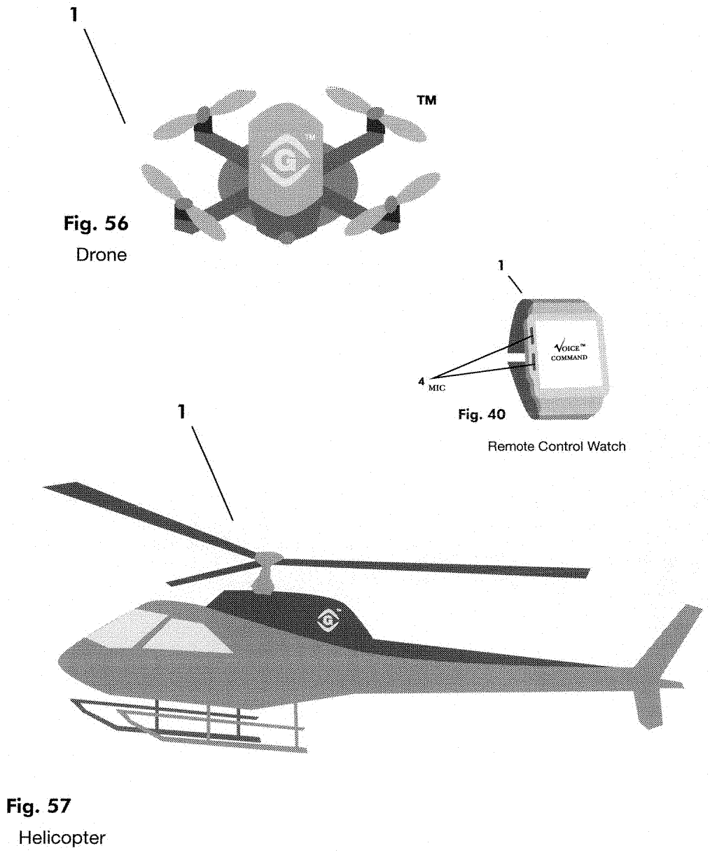

FIG. 56 Shows. front view a mini drone that runs on synthetic Diamonds and is Al.

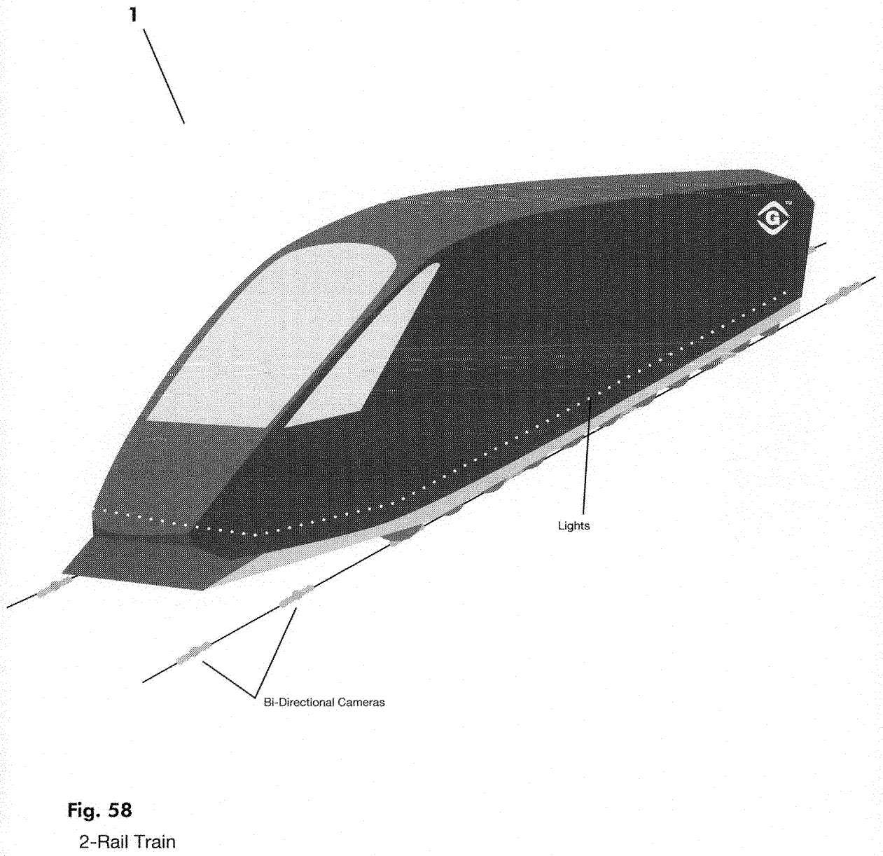

FIG. 57 Shows front right view a Diamond and Plasma body helicopter that can go 500 MPH and has Laser Guns, Capability and is AI works with your smart watch, or cell phone, the helicopter is stealth also.

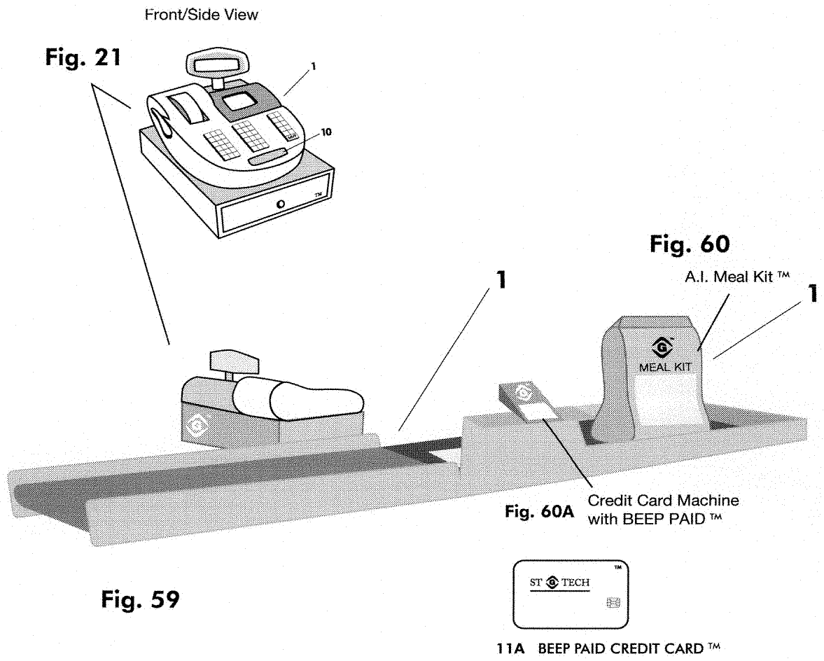

FIG. 58 Shows” front right view of AI Electric Train with Cameras and computers can run on one rail or two, Runs on synthetic diamonds, Runs on Anti Matter also.

FIG. 59 Shows front right side Beep Paid Credit Card just get close to the Smart Cash Register push MVP button for Mobile Verify payment.

FIG. 60 Shows. shows front right side AI Meal Kit order it will be sent to you anywhere by the Companies Logistics Department. 60A Beep Paid credit card machine™ with Encryption Software in a Pseudonymous format or AI for pick up at store will have grocery store list on Cellphone, or Tablet device.

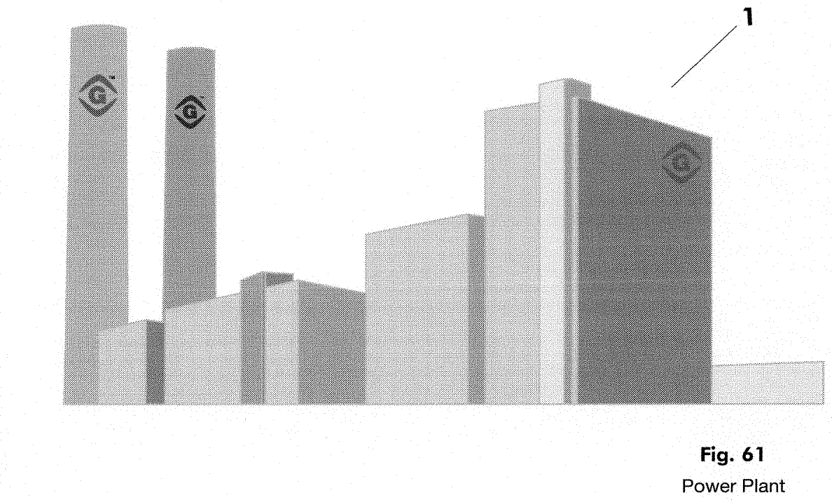

FIG. 61 shows 1. front Power Plant that is Encrypted Software with a Pseudonymous format. Will run on Anti Matter as well.

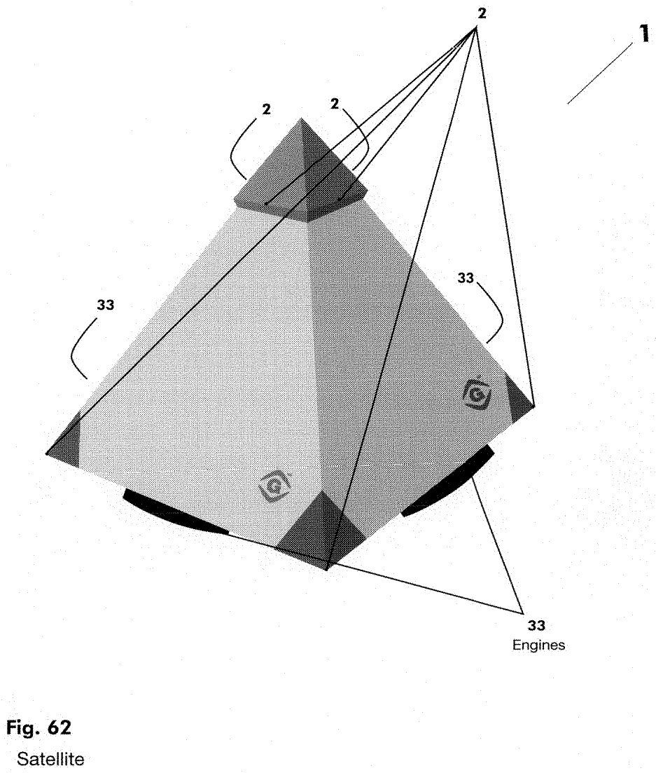

FIG. 62 Shows Satellite AI the Runs on Synthetic Diamonds and Nano Resonators and Sensors by all cameras that are Synthetic Diamond as well with four Engines. With cameras. Will run on Anti Matter. All my figures can be stealth and run on Anti Matter.

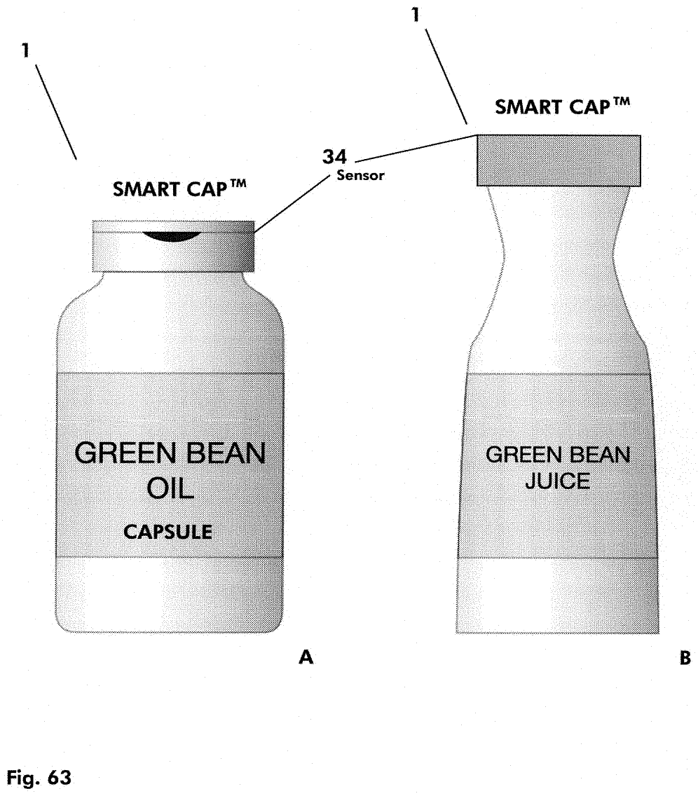

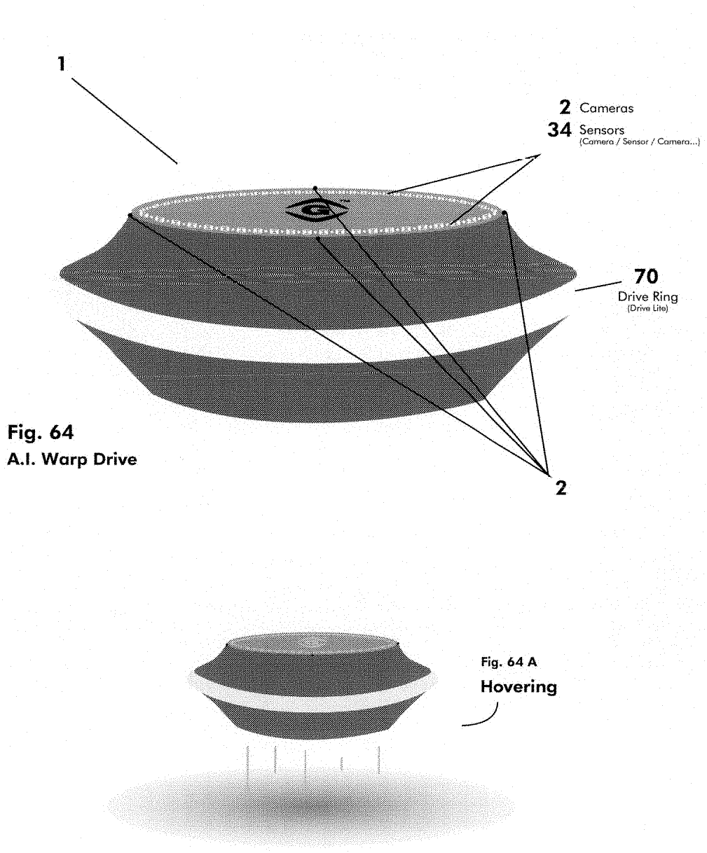

FIG. 63 A Shows. a front view of a smart cap™ with a sensor to call a user and tell them what pill they are taking, it will call the user cell phone or tablet, or Car, any mobile device, And how many pills they have took, and what time to take them, it will call, and let you know 63A and 63B both with sensors 34.

### DETAILED DESCRIPTION OF DEVICE

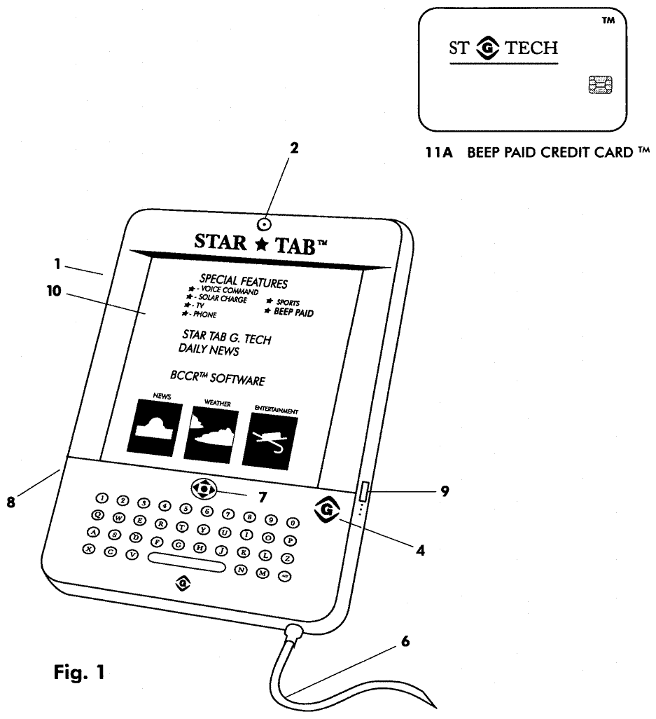

FIG. 1 Shows 1 front view of Solar Tablet™ Verbal 1. with features TV, phone, news, weather, entertainment BCCR™ Built in Credit Card Reader Software™, with camera 2. speaker 4. ear plug port 6. menu button 7. beep paid credit card 11A attachable and detachable keyboard 8. USB port 9. Light Window Port 10. Scan close to software terminal for beep paid credit card 11A.

FIG. 2 Shows 1 back view of solar tablet 1. with back facing camera 2. ear plug port 6. and built in credit card reader 11.A and boomerang Swiss G logo. FIG. 2. A Built in Projector Camera 2. On Tablet Back, solar screen 10 Swiss G logo.

FIG. 3 Shows 1 solar tablet for Lil kids tablet 1. with features and camera 2. speaker 4. with ear plug port 6. and menu button 7. attachable and detachable keyboard 8. USB port 9. Light Window Port (LWP) 10.

FIG. 4 Shows 1 solar tablet™ 1. Features news, weather, entertainment, television, phone, built in credit card reader software, with camera 2. speaker 4. menu button 7. USB port 9. and Light Window Port (LWP) 10. FIG. 4A 5 finger print scanner on the tablet 13A.

FIG. 5 Shows 1 actual attachable and detachable keyboard 8. ear plug port 6. menu button 7.

FIG. 6 Shows 1 solar wireless Desk Tab™ 1. with camera 2. with verbal command buttons for turning on and off 3. speaker 4. And where it is attachable and detachable Desk tab™ 8. finger print scanner on screen 13A.

FIG. 7 Shows 1 front view solar wireless keyboard 5. and Light Window Port (LWP) 10. FIG. 8 Shows 1 front view of a solar wireless mouse 1. with a Light Window Port (LWP) 10.

FIG. 9 Shows 1 front view of wireless solar verbal command television 1. with a camera 2. USB port 9. Light Window Port (LWP) 10. built in wireless receiver 18. 9 A shows UHD flash drive for USB in back of TV for Streaming movies. 9B back view upper right corner and bottom left corner and right and left side view of USB Port.

FIG. 1O Shows 1 front view of a solar verbal remote control 1. with VC on and VC off button 3. speaker 4. Light Window Port 10.

FIG. 11. Shows 1 front view of a solar verbal command laptop 1. with camera 2. VC on and VC off buttons 3. speaker 4. and Light Window Port (LWP) 10.13 A 5 finger print scanner.

FIG. 12 Shows 1 front view of a solar attachable and detachable tablet, called the Tab lap™ 1. with phone, TV, weather, news, entertainment, with built in software credit card reader, with camera 2. keyboard 5. where it is attachable and detachable keyboard 8. Light Window Port (LWP) 10.

FIG. 13 Shows 1 front view of a solar touch screen on the top and push button on the bottom verbal command Flip Phone™ 1. with camera 2. speaker 4. menu button 7. and Light Window Port (LWP) 10. Runs on Nano Resonators.

FIG. 14 Shows 1 front view of a solar verbal command cell phone 1. camera 2. speaker 4. menu button 7. Light Window Port (LWP) 10. 14B show side way 5 finger print scanner 13 A, 11A 3 finger print scanner 11A beep paid credit card. FIG. 14A Cell Phone.

FIG. 15 Shows 1 back facing camera 2. and VC on and off buttons 3. of solar verbal command cell phone 1. FIG. 15B Shows back of cell phone 1. with built in projector 2. solar screen 10.

FIG. 16 Shows 1 front view of solar verbal command MP3 player 1. with camera 2. speaker 4. ear plugs 6. menu button 7. Light Window Port (LWP) 10. and Built in Beep paid credit card reader 11A.

FIG. 17 Shows 1 back view of a solar verbal command MP3 player 1. with back facing camera 2. and VC on and VC off buttons 3.

FIG. 18 Shows front right side view of an attachable and detachable MP3 player 1.

FIG. 19 Shows 1 front right side view of attachable and detachable keyboard 8.

FIG. 20. Show 1 front right side view 1. of attachable and detachable keyboard 8. With camera 2. on MP3 player and how it works 8. Will run on tiny diamond Nano Resonators.

FIG. 21 Shows 1 front left angle view of a solar wireless cash register 1. with Light window Port (LWP) 10. FIG. 22 Shows 1 front right angle view of a wireless scanner 1. with Light Window Port (LWP) 10.

FIG. 23 Shows 1 front view of Star™ wireless headset for music 1. and speaker 4. On both sides solar window port with mic on both sides.

FIG. 24 Shows 1 front view of wireless ear plugs 1. both run by software, and speaker 4. FIG. 24A Shows 1 wireless earplugs with speaker and solar (LWP) 10. 24B Shows two pair of wireless earplugs with speaker 4.24C shows two pair and one single earplug all with no (LWP).

FIG. 25 Shows 1 front view of a verbal solar portable game player 1. with camera 2. speaker 4. Light Window Port (LWP) 10. With 5 finger print scan 13A

FIG. 26 Shows 1 front view of a solar wireless speaker 1. with Light window Port (LWP) 10. Wireless amplifier 16. with cathode 17. and anode 19. that produce electrons that make sound, and speakers work and wireless receiver 18. in amplifier and on guitars. Broken lines around volume, treble, bass knobs are for illustration only and are no part of invention. Huge Speakers for live bands recording artist as well.

FIG. 27 Shows 1 front view of wireless guitar 1. with wireless receiver 18. FIG. 28 Shows 1 side view of wireless guitar 1. with wireless receiver 18.

FIG. 29 Shows 1 front view of a solar wireless smart watch 1. with camera 2. features, TV, verbal can be made of stainless steel also.

Commands speaker 4. on the right side and microphone on the left side, Light Window Port (LWP) 29A AI watch with movie screen 29B side view of smart watch 29C front view of smart watch 29C and D with TV on it.

30.29 FIG. 30 Shows 1 front view of a solar 3 way wireless radio 1. with 5 Light Window Ports (LWP) 10 that run on Nano Resonators.

FIG. 31 Shows 1 front view of a solar cell phone tower 1. Light Window Port (LWP) 10. Wireless transmitter generator 18

Solar panels 21. Solar battery pack 22. 31 A with generator, wind turbine 31B water fuel pump cell phone tower 31C wireless transmitter 18. Generator 31D. Solar panels 21. Water Fuel Cell Solar laser pump 22. Light window Port 10.

FIG. 32 Shows 1 front right view AI Augmented Glasses for movies making movies Video, Music wireless reality Glasses take Pictures, by AI voice command wireless produce movies on your Glasses music, Streaming movies, Games online forums share anything by AI Phone calls, Television.

FIG. 33 Shows 1 front view wireless lamps, with a Shade A without a shade B and tall lamp C.

FIG. 34C Shows 1 front left side and back view of AI electric car with 2 cameras total 14 cameras, and where positioned, fig. A. dashboard with steering wheel that user speaks into to communicate 4. And repeat song selection manually, and by voice 13 finger push button starter, and 13A finger print scanner. Fig. B. Television and drive and park gear change, fig. D front left view of car with 14 cameras, fig. E SUV front left view with 14 cameras, fig. F SUV left side view and back view fig. G shows left view and back view of SUV with solid steel that will be 3 inches thick the new protection from crashes, fig. H. front left view of AI Unmanned Military Truck Fig. I. left side view and back view with 16 cameras 2 on the inside can be operated with or without a man, all vehicles will have Encryption Software in a Pseudonymous format, that can open and close doors, by AI voice command, Park by AI voice command as well, the car can take pictures also and can understand any foreign language as well, all vehicles will run on synthetic diamond resonators, and Anti Matter also.

FIG. 35 Shows 1 front right view first Mobile Home assistant Called Taji and back view with 8 mic's all around the unit and one front and back facing camera. Sports Television, Phone, Messaging, Radio, Video Conferencing, Music, Foreign Languages Encryption Software in a Pseudonymous format, take it anywhere you go.

FIG. 36 Shows 1 front view first Electronic Cane with camera 2. 36A Solar Wireless earplugs it is AI as well. Sensors 34 to detect a car is coming and when to walk Phone Ready also.

FIG. 37 Shows 1 front view AI Virtual Bank Crypto Currency AI as well, buy and sell anything, clothes, jewelry, property. Cars, insurance.

FIG. 38 Shows 1 front view 5 finger print scan 13A, Airports Check Point, Camera 2.

FIG. 39B Shows 1 front view AI ATM Machine to transaction for Crypto Money by cell phone your watch or mobile device

FIG. 40 Shows 1 front view AI Watch for Toys

FIG. 41 Shows 1 frontside view AI toy Alligator

FIG. 42 Shows 1 front side view AI Toy Komoto Dragon KOKO

FIG. 43 Shows 1 front side view AI toy Crocodile

FIG. 44 Shows 1 front right side AI Electric Motorcycle

FIG. 45 Shows 1 front side Diamond Synthetic Mother Board Graphic Processing unit

FIG. 46 Shows 1 front right side AI Jet fighter that will have Mach 66 speed harness by Hydrogen, Helium, Methane Gas Solar with three modes 1^{st} Jet, 2^{nd} Supersonic 3^{rd} Rocket all from the same aircraft that could stay in orbit for ten years or longer body made of Synthetic Diamonds, and Anti Matter, the body made of synthetic diamonds Plasma to make it front Stealth, with ICBM ability and laser Guns as well this is the ultimate 21^{st} Century Fighter, with Nano Resonators. With 13 Camera on the Jet 46B is the Rocket 46 C is the AI Helmet. With Infrared light camera 2 on top of helmet. will run on Anti Matter. Laser Guns on right and left bottom view 66. Bomb Chamber 77. The windows on the Planes, commercial and jet fighters will be made of synthetic diamonds, 21 cameras windows made of Synthetic Diamonds on all Planes,

FIG. 46 D Shows 1 front right view of AI Jet Fighters formation that be totally unmanned as well

FIG. 47 Shows 1 front view all Diamond Wafer that is Black Diamond (aka) Carbonado that Microchips will be made from, sprinkled with synthetic diamond crystals.

FIG. 48 Shows 1 front view all Synthetic Diamond Wafer that Microchips will be made from Sprinkled with synthetic diamond crystals.

FIG. 49 Shows 1 front view Smart washer that will call user and tell him when the load is finished washing.

FIG. 50 Shows 1 front view Smart Dryer that will also call user on their Cell Phone or any mobile device.

FIG. 51 Shows 1. front view Set of Dentures that will be made from Synthetic Diamonds.

FIG. 52 Shows 1. front view Knee Replacement as well will be made from Synthetic Diamond 52 A Scalpel 52B insulin Pump 34 wireless sensor. Digital Screen Readout. With Encryption Software in a Pseudonymous format.

FIG. 53 Shows 1. front right view Electric AI 18 Wheeler with Braces on the side and back to stop cars from running under the truck. 53A Back of Truck.

FIG. 54 Shows 1. front right view AI Electric Cruise Ship that run on diamonds.

FIG. 55 Shows 1. front right view of AI Data Center that is wireless Solar with Diamond Resonators Coolant System, 55A and 55B the Data Center will have 10,000 processing chips, and 33,000 graphics processors, the system will run on synthetic diamonds.

And Servers, and drives, all run on Synthetic Diamonds.

FIG. 56 Shows 1. front view a mini drone that runs on synthetic Diamonds and is AI.

FIG. 57 Shows 1. front right view a Diamond and Plasma body helicopter that can go 500 MPH and has Laser Guns, Capability and is AI works with your smart watch, or cell phone, the helicopter is stealth also.

FIG. 58 Shows 1. front right view of AI Electric Train with Cameras and computers can run on one rail or two. Runs on synthetic diamonds, Runs on Anti Matter also.

FIG. 59 Shows 1. front right side Beep Paid Credit Card just get close to the Smart Cash Register push MVP button for Mobile Verify payment.

FIG. 60 Shows 1. front right side AI Meal Kit order it will be sent to you anywhere by the Companies Logistics Department. 60A Beep Paid credit card machine™ with Encryption Software in a Pseudonymous format or AI for pick up at store will have grocery store list on Cellphone, or Tablet device.

FIG. 61 Shows 1. front Power Plant that is Encrypted Software with a Pseudonymous format. Will run on Anti Matter as well.

FIG. 62 Shows 1. Satellite AI the Runs on Synthetic Diamonds and Nano Resonators and Sensors by all cameras that are Synthetic Diamond as well with four Engines 33. With 8 cameras. Will run on Anti Matter. All my figures can be stealth and run on Anti Matter.

FIG. 63 A Shows 1 a front view of a smart cap™ with a sensor to call a user and tell them what What pill they are taking, it will call the user cell phone or tablet, or Car, any mobile device, And how many pills they have took, and what time to take them, it will call, and let you know 63A and 63B both with sensors 34.

What is claimed is:

1. A Diamond Nano Resonator Semiconductor Comprising:
A Diamond Coated Synthetic Diamond, and Sensor for Cars, Trucks, Trains, Diamonds Coated Smart Watch. Power Plants, cell phones tower, mother board circuits, commercial air planes, Jet planes, And Rockets, Satellites, cell phones, Tablets, three way radio, Data Centers, the commercial planes, and jets, and rockets will run on anti matter; the servers and drives will run on synthetic diamonds, Because there is nothing that transfer heat like Synthetic Diamonds with Encryption Software in a Pseudonymous Format, the diamonds can work any electronic device.

2. As in claim 1 The Device of claim 2 further comprising capable of Cruise Ships, Helicopters, all running on Synthetic Diamonds; insulin pumps, EKG, pace makers for the heart, any medical equipment, will have Encryption Software in a pseudonymous format.

3. A Electronic Kane as in claim 1 with wireless ear plugs with a camera and sensor to see when an oncoming car is near, or the light changes, the sensor can detect cars, the wireless earplugs will tell The blind person what to do, when walk or stop this Al Kane is for the Blind, Phone ready.

4. A Smart Television as in claim 1 with better picture from synthetic diamonds resonators with USB ports in the front and back, a user can a USB drive for steaming movies, wireless standard size, for Cell phones, MP3 Players, Tablets as well.

5. A Smart Watch as in claim 1 that is capable of working with airplanes, with a camera on it for detecting infrared to know where soldiers are at all times to stop friendly fire, a pilot can talk to the Unit at all times and will know where they are and their position, the Al helmet works with the watch.

6. A Space station as in claim 1 that will stay in space for a hundred years or more that will be harness By the Solar, Hydrogen, Helium, Methane gas, that runs on anti matter, like a space hotel.

7. A three mode Jet as in claim 1 first it take off like a normal plane from the ground, vertical or The traditional runway, the second mode it go to speed of supersonic speed, the third mode is Rocket with Mach 66 Speed it can go into Space to Mars and back thirteen times within a year How, with Anti Matter, and Synthetic Diamonds Resonators, that can transfer heat, and conduct electricity like Nothing ever heard of massive, robust power light year technology, the first in history Nano Technology with microscopic power, it will take us there, the airplane will armed with laser guns, it is stealth with plasma body and synthetic diamonds it can shoot ICBM capability synthetic diamond sensors harness by hydrogen, helium, and methane gas and solar panels.

8. A data center as in claim 1 that is solar, and runs on synthetic diamond Nano Resonators made in Any size and shape that can transfer heat, and conduct electricity faster and better than anything known to man, Synthetic Diamond Panels, as an cooling system shown in FIGS. 55A and 55B to keep the data room cool at all times, the servers and drives are Synthetic Diamond as well the data center will have 10,000 processing chips and 33,000 graphics processors, the system will run on synthetic diamonds this is a Super Computer.

9. All units as in claim 1 will run on Diamond Nano Resonators that are synthetic for electronic devices all from the diamonds the size of a single strand of human hair, that can power anything in space or earth, AI meal kit order from store to pick up or home delivery, view store list on phone, or tablet.

10. The first Al Car as in claim 1 with 14 camera's and with the only realistic place to speak is the steering wheel with microphone speakers on both sides, A television in the dash board that runs on Diamond Nano resonators, and Solar light ports, because the car can transfer heat and conduct electricity so fast it will run indefinitely, it never needs fueling because it is Electric Car the best it is made to run without fuel, and is Stand alone the user don't need a phone to talk or communicate With the Car, The Smart Car will have Encryption Software in a Pseudonymous format.

11. A wireless assistant first with a camera as in claim 1 with front and back facing camera's, capable Of watching Television, video conferencing, phone as well, music, taking pictures, foreign languages, Messaging, Radio, Al voice command, streaming movies, sports, sorting pictures, mobile the user can take it anywhere, solar panels, it runs on Diamond coated Nano resonators semiconductor ten microphones, three speakers armed with protection with Encryption Software in a Pseudonymous format to stop hackers.

12. A Solar cell phone tower as in claim 1 and a water fuel cell phone tower with a generator that's runs on a semiconductor of diamonds coated synthetic, that handles traffic data for electronic devices like cell phones, and mp3 players.

13. A Augmented pair of glasses as in claim 1 that streams movies, makes movies, take pictures by Al Voice command runs on a Diamond synthetic Nano resonator with two speakers on the side to talk into and Encryption Software in a Pseudonymous format phone calls made also.

14. A Smart washer and dryer as in claim 1 that will call the user when the clothes are washing and drying as well, and they are finished washing and drying the software will call the user cell phone, or tablet any mobile device that runs on a diamond coated Nano Resonators semi conductor.

15. A All Diamond Synthetic Diamond Wafer as in claim 1 sprinkle with small grains of synthetic diamonds under low pressure mixed with Methane Gas and Hydrogen, that can produced a Wafer That will make microchips for semiconductors; and an all Black Diamond known as Carbonado Wafer As well to make microchips as well, but this is a rare element, so most will Synthetic Diamond made.

16. A all Diamond set of Dentures as in claim 1 Made of Synthetic Diamond that is twice as hard As diamond found in the earth; FIG. 51 and Synthetic Diamond Bones, for knee replacement FIG. 52 and Doctors Scalpel FIG. 52A and Dental implants as well any Bone needed for the Body.

17. Crypto Currency as in claim 1 the user can have insurance for the same amount that is in the Bank example if you have a Billion Dollars in your account than you are insured for that amount; And Government Regulation is accepted; this is new software will not be one sided, in the past ii f the user has five hundred million in the bank the user is only insured for two hundred thousand dollars, or What the Government rate is at that time, the crypto currency ATM, the user can get coins back by Al on a Cell Phone, Tablet or any mobile device.

18. A Software Application as in claim 1 to stop hacking of Government Agency; and Department stores, Banks, Health Care Data on Digital Medical Equipment, Business Medical Records, Social Security Numbers; Hospital Records, any Private Records, all filed and Protected by Encryption Software in a Pseudonymous format; the Potential Hack, cannot get in the Stack; they Will never get a chance to see any Data, because no Data will be filed in Plain Text ever, a smart cap for pills tells what pill you are taking and how many to take the sensor will call your cell phone or tablet to let user know.

19. A DVD Catalog as in claim 1 will never by Physical buy movies and music that stay in your ownership once a user pays the movie studio, and the music company it will stay on your mobile Device, cell phone, tablet, and the Television can load the Software Application; the TV will have Encryption Software in a Pseudonymous format and each Television will have its own IP Address.

20. A voting system for voters to use a machine with Encryption Software, in a Pseudonymous format in any foreign language worldwide.

21. A Encryption Software in a Pseudonymous format, Stealth Submarine, Synthetic diamond body.

22. An AI Warp Drive Rocket as in claim 1 a smart watch to control the AI Plane that will have a warp drive, that is attachable and detachable in the front hood area of Plane, four Ft long and wide, Just say Warp drive and it will up to take the air craft into Hyper Space this is Mode Four, with a Photon force Shield to defend against asteroids, debris, comets, black holes, Gas, dust, with Synthetic Diamond Sensors; and a Gravity Drive to Produce Synthetic Gravity, the Sensors will let the Star Craft know when an Object is moving towards the Star Ship, AI also as well, will quickly notify the AI unmanned Space Craft is well equipped, man cannot handle Speeds up to 71,506,481,482,063 he can override the craft but that will not be needed, the Photon Shield produces anti gravity, Cameras all through out the Star Ship inside and Outside to view the Star Ship at all times, AI is very Vital to avoid objects the entire Star Ship will work Better with AI, the warp drive will harness Solar Energy as well, will run on Anti Matter also.

23. A pair of wireless ear plugs as in claim 1 for heads of state and President worldwide in any foreign language example the President of France has a wireless earplug in a meeting with the President of America when he speaks it will come out in English to the President of America, and likewise when the President of America speaks it will come out in French; there is no need for an interpreter just speak into the wireless ear plug.

24. A Software program as in claim 1 that allows users to pay their cell phone or mobile device bill or cable bill by AI, just sign up for the program.
